(19) United States
(12) Patent Application Publication
(10) Pub. No.: US 2024/0250013 A1
(43) Pub. Date: Jul. 25, 2024

(54) RADIO FREQUENCY MODULE, COMMUNICATION DEVICE, AND METHOD OF MANUFACTURING RADIO FREQUENCY MODULE

(71) Applicant: Murata Manufacturing Co., Ltd., Nagaokakyo-shi (JP)

(72) Inventors: Motoji TSUDA, Nagaokakyo-shi (JP); Kiyoshi AIKAWA, Nagaokakyo-shi (JP); Takashi YAMADA, Nagaokakyo-shi (JP); Toshiki MATSUI, Nagaokakyo-shi (JP)

(73) Assignee: Murata Manufacturing Co., Ltd., Nagaokakyo-shi (JP)

(21) Appl. No.: 18/583,970

(22) Filed: Feb. 22, 2024

Related U.S. Application Data
(63) Continuation of application No. PCT/JP2022/029901, filed on Aug. 4, 2022.

(30) Foreign Application Priority Data
Aug. 24, 2021 (JP) 2021-136233

(51) Int. Cl. H01L 23/498; H01L 23/538; H01L 23/552; H01L 25/00; H01L 25/10

(52) U.S. Cl. CPC H01L 23/49838; H01L 23/5386; H01L 25/105; H01L 25/50; H01L 23/552

(57) ABSTRACT

A radio frequency module including a mounting substrate, a first electronic component, a second electronic component and a first connection terminal, a second connection terminal, a first resin layer, and a second resin layer. The second electronic component and the first connection terminal are disposed on a second main surface of the mounting substrate. The second connection terminal is connected to the first connection terminal, and is disposed on a side of the first connection terminal opposite to the mounting substrate side. The first resin layer covers at least a part of the second electronic component, and covers at least a part of the first connection terminals. The second resin layer is disposed on the first resin layer, and covers at least a part of the second connection terminal. The second connection terminal is located inside the first connection terminal in a plan view in a thickness direction of the mounting substrate.

### CROSS-REFERENCE TO RELATED APPLICATIONS

This is a continuation application of PCT/JP2022/029901, filed on Aug. 4, 2022, designating the United States of America, which is based on and claims priority to Japanese Patent Application No. JP 2021-136233, filed on Aug. 24, 2021. The entire contents of the above-identified applications, including the specifications, drawings and claims, are incorporated herein by reference in their entirety.

### TECHNICAL FIELD

The present disclosure generally relates to a radio frequency module, a communication device, and a method of manufacturing the radio frequency module, and more specifically, to a radio frequency module including a mounting substrate, a communication device including the radio frequency module, and a method of manufacturing the radio frequency module including the mounting substrate.

### BACKGROUND ART

Patent Document 1 describes a radio frequency module including a module substrate (mounting substrate), a filter (first electronic component), a semiconductor IC (second electronic component), and a plurality of columnar electrodes. The module substrate has a first main surface and a second main surface. The filter is mounted on the first main surface of the module substrate. The semiconductor IC is mounted on the second main surface of the module substrate. The plurality of columnar electrodes are disposed on the second main surface of the module substrate.

### CITATION LIST

### Patent Literature

Patent Document 1: International Publication No. WO 2020/071021

### SUMMARY OF DISCLOSURE

### Technical Problem

In the radio frequency module as described in Patent Document 1, it is desired that the columnar electrode is thinned as a size of the radio frequency module is reduced. Meanwhile, assuming the columnar electrode is thinned, an electric resistance is increased, and there is an issue that a signal loss is increased.

An object of the present disclosure is to provide a radio frequency module capable of reducing a signal loss while achieving reduction in size, a communication device, and a method of manufacturing the radio frequency module. Solution to Problem

According to an aspect of the present disclosure, there is provided a radio frequency module including a mounting substrate, a first electronic component, a second electronic component and a first connection terminal, a second connection terminal, a first resin layer, and a second resin layer. The mounting substrate has a first main surface and a second main surface facing each other. The first electronic component is disposed on the first main surface of the mounting substrate. The second electronic component and the first connection terminal are disposed on the second main surface of the mounting substrate. The second connection terminal is connected to the first connection terminal and disposed on a side of the first connection terminal opposite to a mounting substrate side. The first resin layer covers at least a part of the second electronic component and covers at least a part of the first connection terminal. The second resin layer is disposed on the first resin layer and covers at least a part of the second connection terminal. The second connection terminal is located inside the first connection terminal in a plan view in a thickness direction of the mounting substrate.

According to another aspect of the present disclosure, there is provided a radio frequency module including a mounting substrate, a first electronic component, a second electronic component and a first connection terminal, a second connection terminal, a first resin layer, and a second resin layer. The mounting substrate has a first main surface and a second main surface facing each other. The first electronic component is disposed on the first main surface of the mounting substrate. The second electronic component and the first connection terminal are disposed on the second main surface of the mounting substrate. The second connection terminal is connected to the first connection terminal and disposed on a side of the first connection terminal opposite to a mounting substrate side. The first resin layer covers at least a part of the second electronic component and covers at least a part of the first connection terminal. The second resin layer is disposed on the first resin layer and covers at least a part of the second connection terminal. A shape of each of the first connection terminal and the second connection terminal is a columnar shape. An area of the first connection terminal is larger than an area of the second connection terminal in a plan view in a thickness direction of the mounting substrate.

According to still another aspect of the present disclosure, there is provided a communication device including the radio frequency module, and a signal processing circuit. The signal processing circuit is connected to the radio frequency module.

According to still another aspect of the present disclosure, there is provided a method of manufacturing a radio frequency module including a step of preparing a mounting substrate that includes a first main surface and a second main surface facing each other, and a step of forming a metal member on the second main surface of the mounting substrate. The method of manufacturing the radio frequency module further includes a step of disposing an electronic component on the second main surface of the mounting substrate, and a step of forming a first resin member on a second main surface side of the mounting substrate to cover at least a part of the electronic component. The method of manufacturing the radio frequency module further includes a step of forming a first resin layer by polishing a main surface of the first resin member on an opposite side to a mounting substrate side such that a main surface of the first connection terminal formed from the metal member on an opposite side to the mounting substrate side is exposed. The method of manufacturing the radio frequency module further includes a step of forming a second resin member on a side of the first resin layer opposite to a mounting substrate side, and a step of forming a second resin layer by forming a through-hole at a part of the second resin member facing the first connection terminal in a thickness direction of the mounting substrate. The method of manufacturing the radio frequency module further includes a step of forming a second connection terminal in the through-hole of the second resin layer. The second connection terminal is located inside the first connection terminal in a plan view in the thickness direction of the mounting substrate. Advantageous Effects of Disclosure

With a radio frequency module, a communication device, and a method of manufacturing the radio frequency module according to an aspect of the present disclosure, it is possible to reduce a signal loss while achieving reduction in size.

### BRIEF DESCRIPTION OF DRAWINGS

FIG. 1 is a bottom view of a radio frequency module according to Embodiment 1.

FIG. 2 is a cross-sectional diagram taken along line X-X in FIG. 1, related to the above radio frequency module.

FIGS. 3A and 3B are cross-sectional diagrams of main portions of the above radio frequency module.

FIG. 4 is a circuit configuration diagram of a communication device including the above radio frequency module.

FIG. 5 is a cross-sectional diagram of a step for explaining a method of manufacturing the above radio frequency module.

FIG. 6 is another cross-sectional diagram of the step for explaining the method of manufacturing the above radio frequency module.

FIG. 7 is still another cross-sectional diagram of the step for explaining the method of manufacturing the above radio frequency module.

FIG. 8 is still another cross-sectional diagram of the step for explaining the method of manufacturing the above radio frequency module.

FIG. 9 is still another cross-sectional diagram of the step for explaining the method of manufacturing the above radio frequency module.

FIG. 10 is still another cross-sectional diagram of the step for explaining the method of manufacturing the above radio frequency module.

FIG. 11 is still another cross-sectional diagram of the step for explaining the method of manufacturing the above radio frequency module.

FIG. 12 is still another cross-sectional diagram of the step for explaining the method of manufacturing the above radio frequency module.

FIG. 13 is a bottom view of a radio frequency module according to Embodiment 2.

FIG. 14 is a cross-sectional diagram taken along line X-X in FIG. 13, related to the above radio frequency module.

FIG. 15 is a cross-sectional diagram of a radio frequency module according to Modification Example of Embodiment 2.

FIG. 16 is a bottom view of a radio frequency module according to Embodiment 3.

FIG. 17 is a bottom view of a radio frequency module according to Embodiment 4.

FIG. 18 is a cross-sectional diagram taken along line X-X in FIG. 17, related to the above radio frequency module.

FIG. 19 is a bottom view of a radio frequency module according to Embodiment 5.

FIG. 20 is a cross-sectional diagram taken along line X-X in FIG. 19, related to the above radio frequency module.

FIG. 21 is a bottom view of a radio frequency module according to Embodiment 6.

FIG. 22 is a cross-sectional diagram taken along line X-x in FIG. 21, related to the above radio frequency module.

FIG. 23 is a cross-sectional diagram of a radio frequency module according to Embodiment 7.

### DESCRIPTION OF EMBODIMENTS

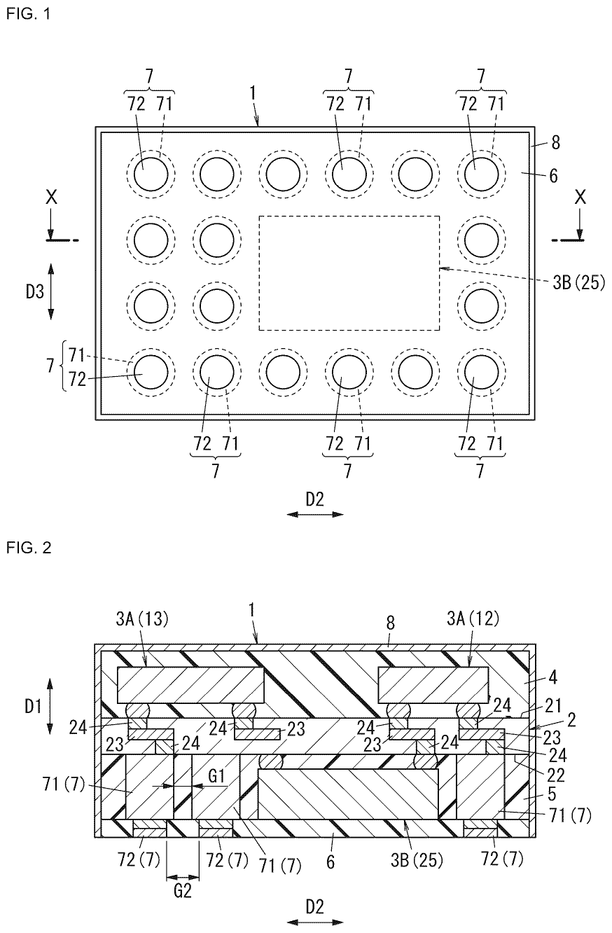

Hereinafter, a radio frequency module, a communication device, and a method of manufacturing the radio frequency module according to Embodiments 1 to 7 will be described with reference to the accompanying drawings. All of FIGS. 1 to 3B and FIGS. 5 to 23 referred to in the following embodiments and the like are schematic diagrams, and each ratio of a size or a thickness of each component in FIGS. 1 to 3B and FIGS. 5 to 23 does not necessarily reflect an actual dimensional ratio.

### Embodiment 1

### (1) Radio frequency Module

A configuration of a radio frequency module 1 according to Embodiment 1 will be described with reference to the drawings.

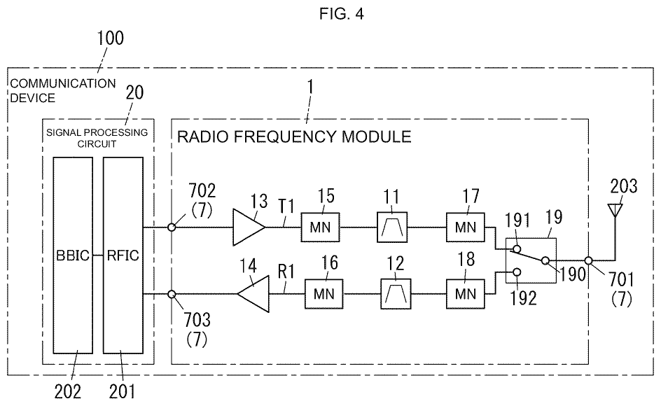

The radio frequency module 1 is used, for example, in a communication device 100 as illustrated in FIG. 4. The communication device 100 is, for example, a mobile phone such as a smartphone. The communication device 100 is not limited to the mobile phone, and may be, for example, a wearable terminal or the like such as a smart watch. The radio frequency module 1 is, for example, a module capable of supporting a fourth generation mobile communication (4G) standard, a fifth generation mobile communication (5G) standard, and the like. The 4G standard is, for example, a third generation partnership project (registered trademark, 3GPP) long term evolution (registered trademark, LTE) standard. The 5G standard is, for example, 5G new radio (NR). The radio frequency module 1 is, for example, a module capable of supporting carrier aggregation and dual connectivity. Carrier aggregation and dual connectivity refer to a technology used for communication that uses radio waves in a plurality of frequency bandwidths at the same time.

The communication device 100 performs communication in a first communication band. More specifically, the communication device 100 performs transmission of transmission signals in the first communication band and reception of reception signals in the first communication band.

The transmission signals and the reception signals of the first communication band are, for example, signals of a frequency division duplex (FDD). The FDD is a wireless communication technology in which different frequency bandwidths are assigned to transmission and reception in wireless communication, and transmission and reception are performed. The transmission signal and the reception signal of the first communication band are not limited to the FDD signals, and may be signals of time division duplex (TDD). The TDD is a wireless communication technology in which the same frequency bandwidth is assigned to transmission and reception in wireless communication, and transmission and reception are switched by the hour.

### (2) Circuit Configuration of Radio frequency Module

Hereinafter, a circuit configuration of the radio frequency module 1 according to Embodiment 1 will be described with reference to FIG. 4. Here, a case will be described in which a transmission signal and a reception signal are FDD signals.

As illustrated in FIG. 4, the radio frequency module 1 according to Embodiment 1 includes a transmission filter 11, a reception filter 12, a power amplifier 13, and a low-noise amplifier 14. Further, the radio frequency module 1 according to Embodiment 1 further includes an output matching circuit 15, an input matching circuit 16, a plurality of (two in the illustrated example) matching circuits 17 and 18, and a switch 19. Further, the radio frequency module 1 according to Embodiment 1 further includes a plurality of (three in the illustrated example) external connection terminals 7.

### (2.1) Transmission Filter

The transmission filter 11 illustrated in FIG. 4 is a filter that passes the transmission signal in the first communication band. The transmission filter 11 is provided on a transmission path T1 that connects an antenna terminal 701 and a signal input terminal 702, which will be described below. More specifically, the transmission filter 11 is provided between the power amplifier 13 and the switch 19 in the transmission path T1. The transmission filter 11 passes a transmission signal in a transmission bandwidth of the first communication band, among radio frequency signals amplified by the power amplifier 13.

### (2.2) Reception Filter

The reception filter 12 illustrated in FIG. 4 is a filter that passes the reception signal in the first communication band. The reception filter 12 is provided on a reception path R1 that connects the antenna terminal 701 and a signal output terminal 703 which will be described below. More specifically, the reception filter 12 is provided between the low-noise amplifier 14 and the switch 19 in the reception path R1. The reception filter 12 passes a reception signal in a reception bandwidth of the first communication band, among radio frequency signals input from the antenna terminal 701.

### (2.3) Power Amplifier

The power amplifier 13 illustrated in FIG. 4 is an amplifier that amplifies the transmission signal. The power amplifier 13 is provided between the signal input terminal 702 and the transmission filter 11 in the transmission path T1. The power amplifier 13 has an input terminal (not illustrated) and an output terminal (not illustrated). The input terminal of the power amplifier 13 is connected to an external circuit (for example, a signal processing circuit 20) with the signal input terminal 702 interposed therebetween. The output terminal of the power amplifier 13 is connected to the transmission filter 11. The power amplifier 13 is controlled by, for example, a controller (not illustrated). The power amplifier 13 may be directly or indirectly connected to the transmission filter 11. In the example in FIG. 4, the power amplifier 13 is connected to the transmission filter 11 with the output matching circuit 15 interposed therebetween.

### (2.4) Low-Noise Amplifier

The low-noise amplifier 14 illustrated in FIG. 4 is an amplifier that amplifies the reception signal with a low noise. The low-noise amplifier 14 is provided between the reception filter 12 and the signal output terminal 703 in the reception path R1. The low-noise amplifier 14 has an input terminal (not illustrated) and an output terminal (not illustrated). The input terminal of the low-noise amplifier 14 is connected to the input matching circuit 16. The output terminal of the low- noise amplifier 14 is connected to an external circuit (for example, the signal processing circuit 20) with the signal output terminal 703 interposed therebetween.

### (2.5) Output Matching Circuit

As illustrated in FIG. 4, the output matching circuit 15 is provided between the transmission filter 11 and the power amplifier 13 in the transmission path T1. The output matching circuit 15 is a circuit for performing impedance matching between the transmission filter 11 and the power amplifier 13.

The output matching circuit 15 has a configuration including an inductor. The inductor of the output matching circuit 15 is provided on an output side of the power amplifier 13 in the transmission path T1. The output matching circuit 15 is not limited to the configuration including one inductor, and may have, for example, a configuration including a plurality of inductors, or a configuration including a plurality of inductors and a plurality of capacitors.

### (2.6) Input Matching Circuit

As illustrated in FIG. 4, the input matching circuit 16 is provided between the reception filter 12 and the low-noise amplifier 14 in the reception path R1. The input matching circuit 16 is a circuit for performing impedance matching between the reception filter 12 and the low-noise amplifier 14.

The input matching circuit 16 has a configuration including an inductor. The inductor of the input matching circuit 16 is provided on an input side of the low-noise amplifier 14 in the reception path R1. The input matching circuit 16 is not limited to the configuration including one inductor, and may have, for example, a configuration including a plurality of inductors, or a configuration including a plurality of inductors and a plurality of capacitors.

### (2.7) Matching Circuit

As illustrated in FIG. 4, the matching circuit 17 is provided between the transmission filter 11 and the switch 19 in the transmission path T1. The matching circuit 17 is a circuit for impedance matching between the transmission filter 11 and the switch 19.

The matching circuit 17 has a configuration including an inductor. The inductor of the matching circuit 17 is provided on an output side of the transmission filter 11 in the transmission path T1. The matching circuit 17 is not limited to the configuration including one inductor, and may have, for example, a configuration including a plurality of inductors, or a configuration including a plurality of inductors and a plurality of capacitors.

As illustrated in FIG. 4, the matching circuit 18 is provided between the reception filter 12 and the switch 19 in the reception path R1. The matching circuit 18 is a circuit for impedance matching between the reception filter 12 and the switch 19.

The matching circuit 18 has a configuration including an inductor. The inductor of the matching circuit 18 is provided on an input side of the reception filter 12 in the reception path R1. The matching circuit 18 is not limited to the configuration including one inductor, and may have, for example, a configuration including a plurality of inductors, or a configuration including a plurality of inductors and a plurality of capacitors.

### (2.8) Switch

The switch 19 illustrated in FIG. 4 switches a filter to be connected to the antenna terminal 701, among the transmission filter 11 and the reception filter 12. In other words, the switch 19 is a switch for switching a path to be connected to an antenna 203 which will be described below. The switch 19 has a common terminal 190 and a plurality of (two in the illustrated example) selection terminals 191 and 192. The common terminal 190 is connected to the antenna terminal 701. The selection terminal 191 is connected to the transmission filter 11. Further, the selection terminal 192 is connected to the reception filter 12.

The switch 19 switches connection states between the common terminal 190 and the plurality of selection terminals 191 and 192. The switch 19 is controlled by, for example, the signal processing circuit 20. The switch 19 electrically connects the common terminal 190 to at least one of the plurality of selection terminals 191 and 192, according to a control signal from an RF signal processing circuit 201 of the signal processing circuit 20.

### (2.9) External Connection Terminal

As illustrated in FIG. 4, the plurality of external connection terminals 7 are terminals for electrically connecting to an external circuit (for example, the signal processing circuit 20). The plurality of external connection terminals 7 include the antenna terminal 701, the signal input terminal 702, the signal output terminal 703, and a plurality of ground terminals (not illustrated).

The antenna terminal 701 is connected to the antenna 203. In the radio frequency module 1, the antenna terminal 701 is connected to the switch 19. In addition, the antenna terminal 701 is connected to the transmission filter 11 and the reception filter 12 with the switch 19 interposed therebetween.

The signal input terminal 702 is a terminal for inputting transmission signals from an external circuit (for example, the signal processing circuit 20) to the radio frequency module 1. In the radio frequency module 1, the signal input terminal 702 is connected to the power amplifier 13.

The signal output terminal 703 is a terminal for outputting a reception signal from the low-noise amplifier 14 to an external circuit (for example, the signal processing circuit 20). In the radio frequency module 1, the signal output terminal 703 is connected to the low-noise amplifier 14.

The plurality of ground terminals are terminals which are electrically connected to a ground electrode of an external substrate (not illustrated) included in the communication device 100 and to which a ground potential is applied. In the radio frequency module 1, the plurality of ground terminals are connected to a ground layer (not illustrated) of a mounting substrate 2. The ground layer is a circuit ground of the radio frequency module 1.

### (3) Structure of Radio Frequency Module

Hereinafter, a structure of the radio frequency module 1 according to Embodiment 1 will be described with reference to the drawings.

As illustrated in FIGS. 1 and 2, the radio frequency module 1 includes the mounting substrate 2, a plurality of (two in the illustrated example) first electronic components 3A, a second electronic component 3B, and a plurality of first connection terminals 71, and a plurality of second connection terminals 72. Further, the radio frequency module 1 further includes a plurality of (three in the illustrated example) resin layers 4 to 6 and a metal electrode layer 8.

The radio frequency module 1 can be electrically connected to the external substrate (not illustrated). The external substrate corresponds to a mother substrate of the communication device 100 (see FIG. 4), such as a mobile phone and a communication device, for example. The fact that the radio frequency module 1 can be electrically connected to the external substrate includes a case where the radio frequency module 1 is directly mounted on the external substrate and a case where the radio frequency module 1 is indirectly mounted on the external substrate. The case where the radio frequency module 1 is indirectly mounted on the external substrate is a case where the radio frequency module 1 is mounted on another radio frequency module mounted on the external substrate, or the like.

### (3.1) Mounting Substrate

As illustrated in FIG. 2, the mounting substrate 2 has a first main surface 21 and a second main surface 22. The first main surface 21 and the second main surface 22 face each other in a thickness direction D1 of the mounting substrate 2. Assuming the radio frequency module 1 is provided at an external substrate, the second main surface 22 faces a main surface of the external substrate, on the mounting substrate 2 side. The mounting substrate 2 is a double-sided mounting substrate in which the plurality of first electronic components 3A are mounted on the first main surface 21 and the second electronic component 3B is mounted on the second main surface 22. In the present embodiment, the thickness direction D1 of the mounting substrate 2 is a first direction (hereinafter, also referred to as a “first direction D1”).

The mounting substrate 2 is a multilayer substrate in which a plurality of dielectric layers are laminated. The mounting substrate 2 has a plurality of conductive layers 23 and a plurality of via-conductors 24 (including through- electrodes). The plurality of conductive layers 23 include a ground layer at a ground potential. The plurality of via- conductors 24 are used for electrical connection of elements (including the first electronic component 3A and the second electronic component 3B described above) mounted on each of the first main surface 21 and the second main surface 22 and the conductive layer 23 of the mounting substrate 2. The plurality of via-conductors 24 are used for electrical connection between the elements mounted on the first main surface 21 and the elements mounted on the second main surface 22 and for electrical connection between the conductive layer 23 of the mounting substrate 2 and the first connection terminal 71.

The plurality of first electronic components 3A are disposed on the first main surface 21 of the mounting substrate 2. The second electronic component 3B and the plurality of first connection terminals 71 are disposed on the second main surface 22 of the mounting substrate 2.

### (3.2) First Electronic Component

As illustrated in FIG. 2, the plurality of first electronic components 3A are disposed on the first main surface 21 of the mounting substrate 2. In the example in FIG. 2, each of the plurality of first electronic components 3A is mounted on the first main surface 21 of the mounting substrate 2. In each of the plurality of first electronic components 3A, a part of the first electronic component 3A may be mounted on the first main surface 21 of the mounting substrate 2, and the rest part of the first electronic component 3A may be built in the mounting substrate 2. In short, each of the plurality of first electronic components 3A is located on the first main surface 21 side of the mounting substrate 2 than the second main surface 22, and has at least a part that is mounted on the first main surface 21. In the present embodiment, one of the plurality of first electronic components 3A is, for example, the reception filter 12, and the other one of the plurality of first electronic components 3A is, for example, the power amplifier 13.

Electronic components constituting the transmission filter 11 are not illustrated in FIG. 2, and are disposed on the first main surface 21 of the mounting substrate 2. More specifically, the electronic components constituting the transmission filter 11 are mounted on the first main surface 21 of the mounting substrate 2. In the electronic component constituting the transmission filter 11, a part of the electronic component may be mounted on the first main surface 21 of the mounting substrate 2, and the rest part of the electronic component may be built in the mounting substrate 2. In short, the electronic component constituting the transmission filter 11 is located on the first main surface 21 side of the mounting substrate 2 than the second main surface 22, and has at least a part that is mounted on the first main surface 21.

Each of the transmission filter 11 and the reception filter 12 is, for example, an acoustic wave filter including a plurality of series arm resonators and a plurality of parallel arm resonators. The acoustic wave filter is, for example, a surface acoustic wave (SAW) filter that uses a surface acoustic wave. Further, each of the transmission filter 11 and the reception filter 12 may include at least one of an inductor and a capacitor connected in series to any one of the plurality of series arm resonators, or may include an inductor or a capacitor connected in series to any one of the plurality of parallel arm resonators.

### (3.3) Second Electronic Component

As illustrated in FIG. 2, the second electronic component 3B is disposed on the second main surface 22 of the mounting substrate 2. In the example in FIG. 2, the second electronic component 3B is mounted on the second main surface 22 of the mounting substrate 2. In the second electronic component 3B, a part of the second electronic component 3B may be mounted on the second main surface 22 of the mounting substrate 2, and the rest part of the second electronic component 3B may be built in the mounting substrate 2. In short, the second electronic component 3B is located on the second main surface 22 side of the mounting substrate 2 than the first main surface 21, and has at least a part that is mounted on the second main surface 22. The second electronic component 3B is, for example, an IC chip 25. In the present embodiment, the IC chip 25 includes the low-noise amplifier 14 and the switch 19.

### (3.4) Matching Circuit

Each of the output matching circuit 15, the input matching circuit 16, and the plurality of matching circuits 17 and 18 is not illustrated in FIG. 2, and is disposed on the first main surface 21 of the mounting substrate 2. Each of the output matching circuit 15, the input matching circuit 16, and the plurality of matching circuits 17 and 18 has a configuration including an inductor as described above. The inductor of each of the output matching circuit 15, the input matching circuit 16, and the plurality of matching circuits 17 and 18 is, for example, a chip inductor. The inductor of each of the output matching circuit 15, the input matching circuit 16, and the plurality of matching circuits 17 and 18 is mounted on the first main surface 21 of the mounting substrate 2. Regarding the inductor of each of the output matching circuit 15, the input matching circuit 16, and the plurality of matching circuits 17 and 18, a part of the inductor is mounted on the first main surface 21 of the mounting substrate 2, and the rest part of the inductor may be built in the mounting substrate 2. In short, the inductor of each of the output matching circuit 15, the input matching circuit 16, and the plurality of matching circuits 17 and 18 is located on the first main surface 21 side of the mounting substrate 2 than the second main surface 22, and has at least a part that is mounted on the first main surface 21. In a plan view in the thickness direction D1 of the mounting substrate 2, an outer edge of the inductor of each of the output matching circuit 15, the input matching circuit 16, and the plurality of matching circuits 17 and 18 has a quadrangle shape.

### (3.5) First Connection Terminal

The plurality of first connection terminals 71 are terminals for electrically connecting the mounting substrate 2 and the second connection terminal 72.

As illustrated in FIG. 2, the plurality of first connection terminals 71 are disposed on the second main surface 22 of the mounting substrate 2. Each of the plurality of first connection terminals 71 is, for example, a columnar (for example, cylindrical) electrode provided on the second main surface 22 of the mounting substrate 2. A material of the plurality of first connection terminals 71 is, for example, metal. Details of the first connection terminal 71 will be described in a field of “ (6) Detailed Structure of First Connection Terminal and Second Connection Terminal”.

### (3.6) Second Connection Terminal

The plurality of second connection terminals 72 are terminals for electrically connecting the plurality of first connection terminals 71 and an external substrate (not illustrated). Each of the plurality of second connection terminals 72 corresponds to at least one of the plurality of first connection terminals 71. In the example in FIG. 2, the plurality of first connection terminals 71 and the plurality of second connection terminals 72 have a one-to-one correspondence.

As illustrated in FIG. 2, each of the plurality of second connection terminals 72 is joined to the corresponding first connection terminal 71 among the plurality of first connection terminals 71. Each of the plurality of second connection terminals 72 is, for example, a columnar (for example, cylindrical) electrode. A material of the plurality of second connection terminals 72 is, for example, metal. Details of the second connection terminal 72 will be described in the field of “ (6) Detailed Structure of First Connection Terminal and Second Connection Terminal”. In the following description, the first connection terminal 71 and the second connection terminal 72 are collectively referred to as the external connection terminal 7, in some cases.

### (3.7) Resin Layer

As illustrated in FIG. 2, the resin layer 4 is disposed on the first main surface 21 of the mounting substrate 2. The resin layer 4 covers the plurality of first electronic components 3A. Here, the resin layer 4 covers an outer peripheral surface of each of the plurality of first electronic components 3A. In addition, the resin layer 4 covers a main surface of each of the plurality of first electronic components 3A, which is on an opposite side to the mounting substrate 2 side. In the present embodiment, the outer peripheral surface of each of the plurality of first electronic components 3A includes four side surfaces including main surfaces of the first electronic component 3A on an opposite side to the mounting substrate 2 side and main surfaces of the first electronic component 3A on the mounting substrate 2 side. The resin layer 4 includes a resin (for example, epoxy resin). The resin layer 4 may include a filler in addition to the resin.

As illustrated in FIG. 2, the resin layer 5 is disposed on the second main surface 22 of the mounting substrate 2. The resin layer 5 covers the second electronic component 3B and the plurality of first connection terminals 71. Here, the resin layer 5 covers an outer peripheral surface of the second electronic component 3B. Further, the resin layer 5 covers an outer peripheral surface of each of the plurality of first connection terminals 71. That is, the resin layer 5 covers at least a part of the second electronic component 3B and at least a part of the first connection terminal 71. In the present embodiment, the outer peripheral surface of the second electronic component 3B includes four side surfaces including main surfaces on an opposite side to the mounting substrate 2 side and main surfaces on the mounting substrate 2 side, of the second electronic component 3B. The resin layer 5 includes a resin (for example, epoxy resin). The resin layer 5 may include a filler in addition to the resin. A material of the resin layer 5 may be the same material as the resin layer 4 or may be a different material. In the present embodiment, a first resin layer is configured with the resin layer 5.

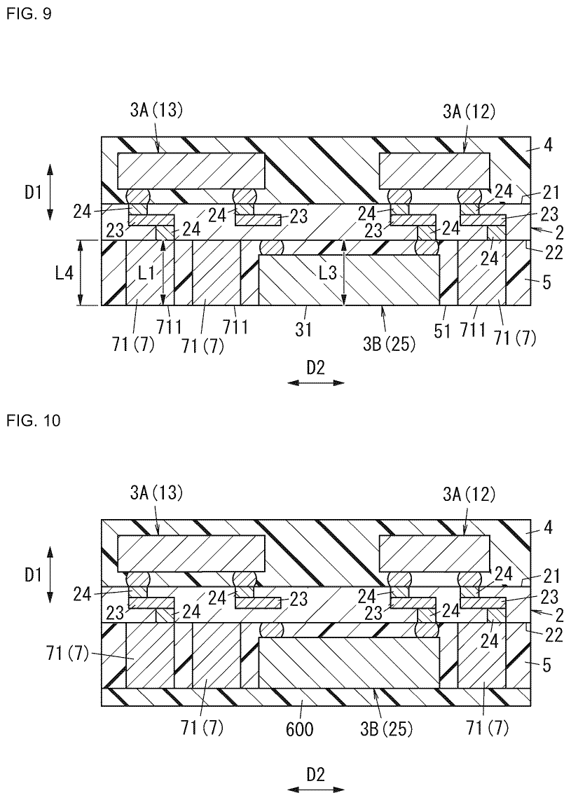

As illustrated in FIG. 2, the resin layer 6 is disposed on a main surface 51 (see FIG. 9) of the resin layer 5, which is on an opposite side to the mounting substrate 2 side. More specifically, the resin layer 6 is disposed on a side of the resin layer 5 opposite to the mounting substrate 2 side, in the thickness direction D1 of the mounting substrate 2. Here, the resin layer 6 covers outer peripheral surfaces of the plurality of second connection terminals 72. That is, the resin layer 6 covers at least a part of the second connection terminal 72. The resin layer 6 includes a resin (for example, epoxy resin). The resin layer 6 may include a filler in addition to the resin. A material of the resin layer 6 may be the same material as the resin layer 5 or may be a different material. In the present embodiment, the material of the resin layer 5 and the material of the resin layer 6 are different from each other. In addition, in the present embodiment, a second resin layer is configured with the resin layer 6.

Here, hardness of the resin layer 5 (first resin layer) is preferably harder than hardness of the resin layer 6 (second resin layer). A scale indicating the “hardness” is, for example, Vickers hardness. The “A is harder than B” means, for example, that a numerical value of Vickers hardness of A is larger than a numerical value of Vickers hardness of B.

At least one of the material of the resin layer 5 and the material of the resin layer 6 is preferably a material having high thermal conductivity. Thus, it is possible to improve heat radiation performance of heat generated in the second electronic component 3B.

### (3.8) Metal Electrode Layer

As illustrated in FIG. 2, the metal electrode layer 8 covers the resin layer 4. The metal electrode layer 8 has conductivity. In the radio frequency module 1, the metal electrode layer 8 is a shield layer provided for the purpose of electromagnetic shielding inside and outside the radio frequency module 1. The metal electrode layer 8 has a multilayer structure in which a plurality of metal layers are laminated. Meanwhile, the present embodiment is not limited to the multilayer structure, and may be one metal layer. One metal layer includes one type or a plurality of types of metals. The metal electrode layer 8 covers a main surface of the resin layer 4 on an opposite side to the mounting substrate 2 side, an outer peripheral surface of the resin layer 4, an outer peripheral surface of the mounting substrate 2, an outer peripheral surface of the resin layer 5, and an outer peripheral surface of the resin layer 6. The metal electrode layer 8 is in contact with at least a part of an outer peripheral surface of the ground layer (not illustrated) of the mounting substrate 2. Thus, a potential of the metal electrode layer 8 can be set to be the same as a potential of the ground layer.

### (4) Detailed Structure of Each Component of Radio Frequency Module

### (4.1) Mounting Substrate

The mounting substrate 2 illustrated in FIG. 2 is, for example, a multilayer substrate including a plurality of dielectric layers (not illustrated) and the plurality of conductive layers 23. The plurality of dielectric layers and the plurality of conductive layers 23 are laminated in the thickness direction D1 of the mounting substrate 2. The plurality of conductive layers 23 are formed in a predetermined pattern determined for each layer. Each of the plurality of conductive layers 23 includes one or a plurality of conductor portions in one plane orthogonal to the thickness direction D1 of the mounting substrate 2. A material of each conductive layer 23 is, for example, copper. The plurality of conductive layers 23 include a ground layer. In the radio frequency module 1, the plurality of ground terminals and the ground layer are electrically connected to each other with the via-conductor 24 and the like of the mounting substrate 2 interposed therebetween. The mounting substrate 2 is, for example, a low temperature co-fired ceramics (LTCC) substrate. The mounting substrate 2 is not limited to the LTCC substrate, and may be, for example, a printed wiring board, a high temperature co-fired ceramics (HTCC) substrate, or a resin multilayer substrate.

Further, the mounting substrate 2 is not limited to the LTCC substrate, and may be, for example, a wiring structure. The wiring structure is, for example, a multilayer structure. The multilayer structure includes at least one insulating layer and at least one conductive layer. The insulating layer is formed in a predetermined pattern. In a case where the number of insulating layers is plural, the plurality of insulating layers are formed in a predetermined pattern determined for each layer. The conductive layer is formed in a predetermined pattern different from the predetermined pattern of the insulating layer. In a case where the number of conductive layers is plural, the plurality of conductive layers are formed in a predetermined pattern determined for each layer. The conductive layer may include one or a plurality of rewiring portions. In the wiring structure, a first surface of two surfaces facing each other in a thickness direction of the multilayer structure is the first main surface 21 of the mounting substrate 2, and a second surface is the second main surface 22 of the mounting substrate 2. The wiring structure may be, for example, an interposer. The interposer may be an interposer using a silicon substrate or may be a substrate having multiple layers.

The first main surface 21 and the second main surface 22 of the mounting substrate 2 are separated in the thickness direction D1 of the mounting substrate 2, and intersect with the thickness direction D1 of the mounting substrate 2. The first main surface 21 of the mounting substrate 2 is, for example, orthogonal to the thickness direction D1 of the mounting substrate 2, and may include, for example, a side surface or the like of a conductor portion as a surface that is not orthogonal to the thickness direction D1 of the mounting substrate 2. In addition, the second main surface 22 of the mounting substrate 2 is, for example, orthogonal to the thickness direction D1 of the mounting substrate 2, and may include, for example, a side surface or the like of a conductor portion as a surface that is not orthogonal to the thickness direction D1 of the mounting substrate 2. Further, the first main surface 21 and the second main surface 22 of the mounting substrate 2 may be formed with a fine roughness portion, a recess portion, or a protruding portion. The mounting substrate 2 has an oblong shape, and may be, for example, a square shape, in the plan view in the thickness direction D1 of the mounting substrate 2.

### (4.2) Filter

Detailed structures of the transmission filter 11 and the reception filter 12 will be described. In the following description, the transmission filter 11 and the reception filter 12 are referred to as filters without distinguishing between the transmission filter 11 and the reception filter 12.

The filter is a one-chip filter. Here, in the filter, for example, each of a plurality of series arm resonators and a plurality of parallel arm resonators is configured with an acoustic wave resonator. In this case, the filter includes, for example, a substrate, a piezoelectric body layer, and a plurality of interdigital transducer electrodes (IDTs). The substrate has a first surface and a second surface. The piezoelectric body layer is provided on the first surface of the substrate. The piezoelectric body layer is provided on a low velocity-of-sound film. The plurality of IDT electrodes are provided on the piezoelectric body layer. Here, the low velocity-of-sound film is directly or indirectly provided on the substrate. In addition, the piezoelectric body layer is directly or indirectly provided on the low velocity-of-sound film. In the low velocity-of-sound film, a velocity of sound of a bulk wave that propagates through the low velocity-of- sound film is lower than a velocity of sound of a bulk wave that propagates through the piezoelectric body layer. In the substrate, a velocity of sound of the bulk wave that propagates through the substrate is faster than a velocity of sound of an acoustic wave that propagates through the piezoelectric body layer. A material of the piezoelectric body layer is, for example, lithium tantalate. A material of the low velocity-of-sound film is, for example, silicon oxide. The substrate is, for example, a silicon substrate.

The piezoelectric body layer may be formed with, for example, any one of lithium tantalate, lithium niobate, zinc oxide, aluminum nitride, or lead zirconate titanate (PZT). In addition, the low velocity-of-sound film may include at least one material selected from a group consisting of silicon oxide, glass, silicon oxynitride, tantalum oxide, and a compound obtained by adding fluorine, carbon, or boron to silicon oxide. In addition, the substrate may include at least one material selected from a group consisting of silicon, aluminum nitride, aluminum oxide, silicon carbide, silicon nitride, sapphire, lithium tantalate, lithium niobate, crystal, alumina, zirconia, cordierite, mullite, steatite, forsterite, magnesia, and diamond.

The filter further includes, for example, a spacer layer and a cover member. The spacer layer and the cover member are provided on the first surface of the substrate. The spacer layer surrounds the plurality of IDT electrodes, in a plan view in a thickness direction of the substrate. The spacer layer has a frame shape (rectangular frame shape), in the plan view in the thickness direction of the substrate. The spacer layer has electric insulation. The material of the spacer layer is, for example, an epoxy resin or a synthetic resin such as polyimide. The cover member has a flat plate shape. The cover member has an oblong shape in the plan view in the thickness direction of the substrate. Meanwhile, the cover member is not limited thereto, and may have, for example, a square shape. In the filter, an outer size of the cover member, an outer size of the spacer layer, and an outer size of the cover member are substantially the same, in the plan view in the thickness direction of the substrate. The cover member is disposed on the spacer layer to face the substrate in the thickness direction of the substrate. The cover member overlaps with the plurality of IDT electrodes in the thickness direction of the substrate, and is separated from the plurality of IDT electrodes in the thickness direction of the substrate. The cover member has electric insulation. A material of the cover member is, for example, an epoxy resin or a synthetic resin such as polyimide. The filter has a space surrounded by the substrate, the spacer layer, and the cover member. In the filter, the space contains a gas. The gas is, for example, air, an inert gas (for example, nitrogen gas), or the like. The plurality of terminals are exposed from the cover member. Each of the plurality of terminals is, for example, a bump. Each bump is, for example, a solder bump. Each bump is not limited to the solder bump, and may be, for example, a gold bump.

The filter may include, for example, a close contact layer interposed between the low velocity-of-sound film and the piezoelectric body layer. The close contact layer is made of, for example, a resin (epoxy resin and polyimide resin). Further, the filter may include a dielectric film either between the low velocity-of-sound film and the piezoelectric body layer, over the piezoelectric body layer, or under the low velocity-of-sound film.

Further, the filter may include, for example, a high velocity-of-sound film interposed between the substrate and the low velocity-of-sound film. Here, the high velocity-of- sound film is directly or indirectly provided on the substrate. The low velocity-of-sound film is directly or indirectly provided on the high velocity-of-sound film. The piezoelectric body layer is directly or indirectly provided on the low velocity-of-sound film. In the high velocity-of-sound film, a velocity of sound of a bulk wave that propagates through the high velocity-of-sound film is faster than a velocity of sound of an acoustic wave that propagates through the piezoelectric body layer. In the low velocity-of-sound film, a velocity of sound of a bulk wave that propagates through the low velocity- of-sound film is lower than a velocity of sound of a bulk wave that propagates through the piezoelectric body layer.

The high velocity-of-sound film is made of diamond-like carbon, aluminum nitride, aluminum oxide, silicon carbide, silicon nitride, silicon, sapphire, lithium tantalate, lithium niobate, a piezoelectric body such as crystal, various ceramics such as alumina, zirconia, cordierite, mullite, steatite, and forsterite, magnesia, diamond, or a material having each of the above materials as a main component, and a material having a mixture of each of the above materials as a main component.

Regarding a thickness of the high velocity-of-sound film, since the high velocity-of-sound film has a function of confinement of acoustic waves in the piezoelectric body layer and the low velocity-of-sound film, the larger the thickness of the high velocity-of-sound film, the more preferable. A piezoelectric substrate may have the close contact layer, the dielectric film, or the like, as another film other than the high velocity-of-sound film, the low velocity-of-sound film, and the piezoelectric body layer.

Each of the plurality of series arm resonators and the plurality of parallel arm resonators is not limited to the acoustic wave resonator described above, and may be, for example, a SAW resonator or a bulk acoustic wave (BAW) resonator. Here, the SAW resonator includes, for example, a piezoelectric substrate and an IDT electrode provided on the piezoelectric substrate. In a case where each of the plurality of series arm resonators and the plurality of parallel arm resonators is configured with the SAW resonator, the filter includes a plurality of IDT electrodes corresponding to the plurality of series arm resonators on a one-to-one basis on one piezoelectric substrate, and a plurality of IDT electrodes corresponding to the plurality of parallel arm resonators on a one-to-one basis. The piezoelectric substrate is, for example, a lithium tantalate substrate, a lithium niobate substrate, or the like. The BAW resonator is, for example, a film bulk acoustic resonator (FBAR) or a solidly mounted resonator (SMR). The BAW resonator has a substrate. The substrate is, for example, a silicon substrate.

### (4.3) Power Amplifier (First Electronic Component)

The power amplifier 13 illustrated in FIG. 4 is, for example, a one-chip IC including a substrate and an amplification function unit. The substrate has a first surface and a second surface that face each other. The substrate is, for example, a gallium arsenide substrate. The amplification function unit includes at least one transistor formed on the first surface of the substrate. The amplification function unit is a function unit having a function of amplifying a transmission signal in a predetermined frequency bandwidth. The transistor is, for example, a heterojunction bipolar transistor (HBT). In the power amplifier 13, a power supply voltage from a controller (not illustrated) is applied between a collector-emitter of the HBT. The power amplifier 13 may include, for example, a DC cut capacitor, in addition to the amplification function unit. The power amplifier 13 is provided with, for example, a flip-chip mounted on the first main surface 21 of the mounting substrate 2 such that the first surface of the substrate is on the first main surface 21 side of the mounting substrate 2. In the plan view in the thickness direction D1 of the mounting substrate 2, an outer peripheral shape of the power amplifier 13 is a quadrangle shape.

### (4.4) IC Chip (Second Electronic Component)

The IC chip 25 illustrated in FIGS. 1 and 2 is, for example, a Si-based IC chip including the low-noise amplifier 14 and the switch 19. In the plan view in the thickness direction D1 of the mounting substrate 2, an outer edge of the IC chip 25 has a quadrangle shape.

### (5) Communication Device

As illustrated in FIG. 4, the communication device 100 includes the radio frequency module 1, the antenna 203, and the signal processing circuit 20.

### (5.1) Antenna

The antenna 203 is connected to the antenna terminal 701 of the radio frequency module 1. The antenna 203 has a transmission function of emitting a transmission signal output from the radio frequency module 1 as a radio wave, and a reception function of receiving a reception signal from an outside as a radio wave and outputting the reception signal to the radio frequency module 1.

### (5.2) Signal Processing Circuit

The signal processing circuit 20 includes the RF signal processing circuit 201 and a baseband signal processing circuit 202. The signal processing circuit 20 processes a signal passing through the radio frequency module 1. More specifically, the signal processing circuit 20 processes a transmission signal and a reception signal.

The RF signal processing circuit 201 is, for example, a radio frequency integrated circuit (RFIC). The RF signal processing circuit 201 performs signal processing on a radio frequency signal.

The RF signal processing circuit 201 performs signal processing, such as upconverting, on a radio frequency signal output from the baseband signal processing circuit 202, and outputs the radio frequency signal on which the signal processing is performed to the radio frequency module 1. The RF signal processing circuit 201 performs signal processing, such as down-conversion, on a radio frequency signal output from the radio frequency module 1, and outputs the radio frequency signal on which the signal processing is performed to the baseband signal processing circuit 202.

The baseband signal processing circuit 202 is, for example, a baseband integrated circuit (BBIC). The baseband signal processing circuit 202 performs predetermined signal processing on a transmission signal from an outside of the signal processing circuit 20. The reception signal processed by the baseband signal processing circuit 202 is used, for example, as an image signal as an image signal for an image display or used as an audio signal for a call.

Further, the RF signal processing circuit 201 also has a function as a control unit that controls connection of the switch 19 included in the radio frequency module 1, based on transmission and reception of the radio frequency signals (transmission signal and reception signal). Specifically, the RF signal processing circuit 201 switches the connections of the switch 19 of the radio frequency module 1 by a control signal (not illustrated). The control unit may be provided outside the RF signal processing circuit 201, and may be provided in the radio frequency module 1 or the baseband signal processing circuit 202, for example.

### (6) Detailed Structure of First Connection Terminal and Second Connection Terminal

Hereinafter, detailed structures of the first connection terminal 71 and the second connection terminal 72 will be described with reference to the drawings.

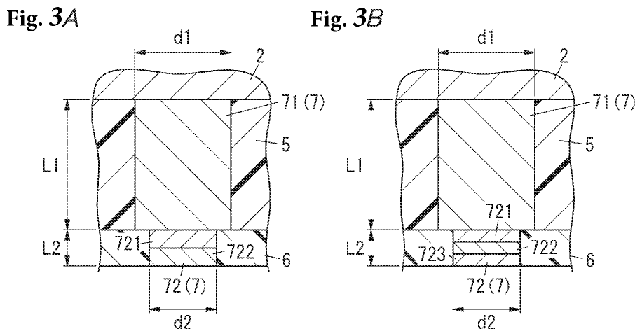

As illustrated in FIGS. 2 and 3A, each of the plurality of second connection terminals 72 is connected to the corresponding first connection terminal 71 among the plurality of first connection terminals 71. The first connection terminal 71 and the second connection terminal 72 are disposed side by side in order of the first connection terminal 71 and the second connection terminal 72 from the mounting substrate 2 side, in the thickness direction D1 of the mounting substrate 2. That is, the second connection terminal 72 is disposed on a side of the first connection terminal 71 opposite to the mounting substrate 2 side, in the thickness direction D1 of the mounting substrate 2. In other words, the first connection terminal 71 is located between the mounting substrate 2 and the second connection terminal 72, in the thickness direction D1 of the mounting substrate 2.

A shape of the first connection terminal 71 and the second connection terminal 72 is, for example, a columnar shape. More specifically, the shape of each of the first connection terminal 71 and the second connection terminal 72 is, for example, a cylindrical shape. As illustrated in FIG. 3A, a diameter d1 of the first connection terminal 71 is larger than a diameter d2 of the second connection terminal 72. Therefore, an area (π×(d1/2)²) of the first connection terminal 71 is larger than an area (π×(d2/2)²) of the second connection terminal 72. In the radio frequency module 1 according to Embodiment 1, the diameter d1 of the first connection terminal 71 is larger than the diameter d2 of the second connection terminal 72, so that it is possible to reduce an electric resistance of the first connection terminal 71 and the second connection terminal 72, and as a result, it is possible to reduce a signal loss, as compared with a case where the diameter of the first connection terminal 71 is as small as the diameter of the second connection terminal 72.

Further, as described above, the diameter dl of the first connection terminal 71 is larger than the diameter d2 of the second connection terminal 72. Therefore, the second connection terminal 72 can be disposed inside the first connection terminal 71, in the plan view in the thickness direction D1 of the mounting substrate 2 (see FIG. 1). Thus, as illustrated in FIG. 2, an interval G2 between the two second connection terminals 72 adjacent to each other in a second direction D2 is larger than an interval G1 between the two first connection terminals 71 adjacent to each other in the second direction D2. As a result, as compared with a case where the interval G2 between the two second connection terminals 72 is the same as the interval G1 between the two first connection terminals 71, it is possible to reduce connection failures assuming the radio frequency module 1 is mounted on the external substrate (not illustrated). Here, the second direction D2 is a direction (right-left direction in FIG. 2) that intersects (orthogonal) with the first direction D1 which is a thickness direction of the mounting substrate 2 and is a direction along a longitudinal direction of the mounting substrate 2.

Further, as illustrated in FIG. 3A, a length L2 of the second connection terminal 72 is smaller than a length L1 of the first connection terminal 71, in the thickness direction D1 of the mounting substrate 2. Thus, since a ratio of the second connection terminal 72 in the external connection terminal 7 is reduced as compared with a case where the length L2 of the second connection terminal 72 is larger than the length L1 of the first connection terminal 71, an electric resistance of the external connection terminal 7 can be reduced, and a strength of the external connection terminal 7 can be increased.

Here, as illustrated in FIG. 3A, the second connection terminal 72 has a two-layer structure including a first layer 721 and a second layer 722. The first layer 721 is, for example, a nickel (Ni) plating layer. The second layer 722 is, for example, a gold (Au) plating layer. That is, a material of the second connection terminal 72 includes nickel and gold. On the other hand, the first connection terminal 71 includes, for example, a copper (Cu) plating layer. That is, a material of the first connection terminal 71 includes copper. In short, the material of the first connection terminal 71 and the material of the second connection terminal 72 are different from each other. In other words, the second connection terminal 72 includes a metal material different from a metal material of the first connection terminal 71.

For example, in a case where the material of the second connection terminal 72 does not include gold but includes copper, adhesion with a solder may be decreased due to oxidation of the copper. On the other hand, with the radio frequency module 1 according to Embodiment 1, the material of the second connection terminal 72 includes gold and is difficult to oxidize, so that adhesion with the solder can be improved.

### (7) Method of Manufacturing Radio Frequency Module

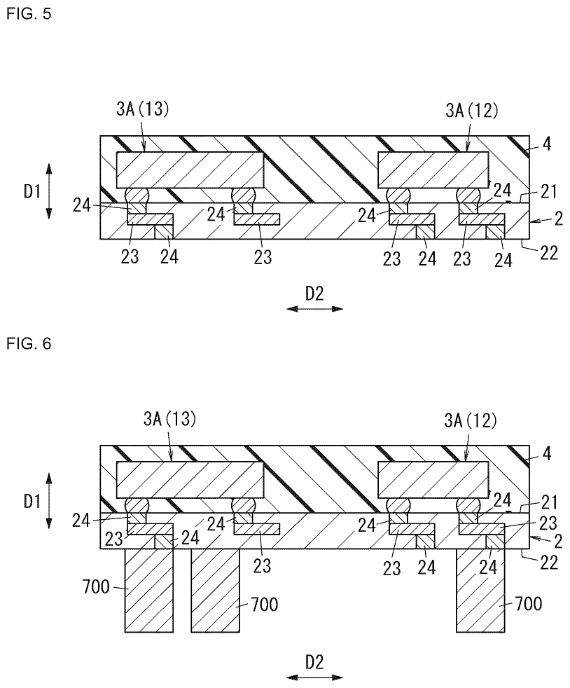

Next, a method of manufacturing the radio frequency module 1 according to Embodiment 1 will be described with reference to FIGS. 2 and 5 to 12. Hereinafter, description will be made assuming that the plurality of first electronic components 3A are mounted on the first main surface 21 of the mounting substrate 2 in advance, and the resin layer 4 is disposed in advance on the first main surface 21 side of the mounting substrate 2 to cover the plurality of first electronic components 3A (see FIG. 5).

The method of manufacturing the radio frequency module 1 includes, for example, a first step, a second step, a third step, a fourth step, a fifth step, a sixth step, a seventh step, and an eighth step, and a ninth step.

The first step is a step of preparing the mounting substrate 2 (see FIG. 5). As described above, the plurality of first electronic components 3A are mounted on the first main surface 21 of the mounting substrate 2, and the resin layer 4 is disposed on the first main surface 21 side of the mounting substrate 2 to cover the plurality of first electronic components 3A. The second step is a step of forming a plurality of metal members 700 on the second main surface 22 of the mounting substrate 2. More specifically, in the second step, as illustrated in FIG. 6, by growing copper plating from the second main surface 22 of the mounting substrate 2 along the thickness direction D1 of the mounting substrate 2, the plurality of metal members 700 serving as bases of the first connection terminals 71 (see FIG. 2) are formed. A shape of each of the plurality of metal members 700 is, for example, a cylindrical shape.

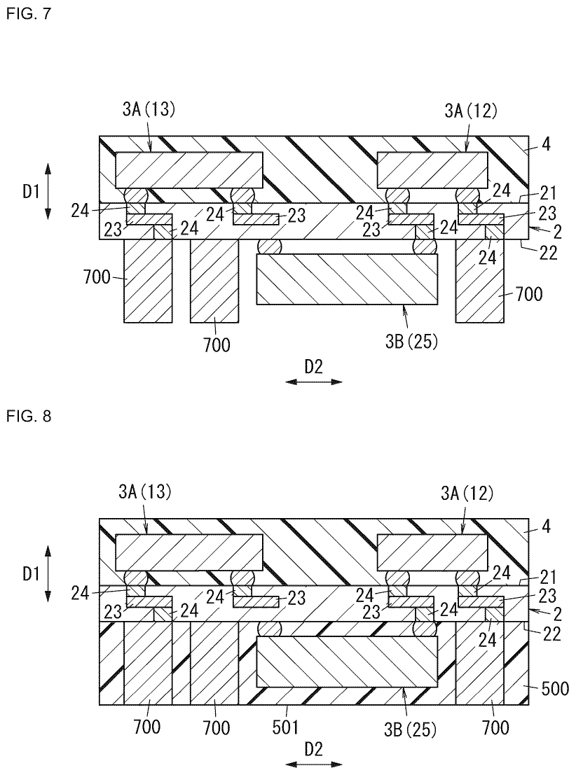

The third step is a step of disposing the second electronic component 3B (electronic component) on the second main surface 22 of the mounting substrate 2. More specifically, in the third step, as illustrated in FIG. 7, the second electronic component 3B is mounted on the second main surface 22 of the mounting substrate 2. The fourth step is a step of forming a resin member 500 (first resin member) on the second main surface 22 side of the mounting substrate 2. More specifically, in the fourth step, as illustrated in FIG. 8, the resin member 500 serving as a base of the resin layer 5 is formed on the second main surface 22 side of the mounting substrate 2 to cover an outer peripheral surface of the second electronic component 3B, a main surface of the second electronic component 3B on an opposite side to the mounting substrate 2 side, and an outer peripheral surface of each of the plurality of metal members 700.

In the fifth step, by using, for example, a polishing machine, a main surface 501 (see FIG. 8) of the resin member 500 on an opposite side to the mounting substrate 2 side is polished to form the resin layer 5 (first resin layer). More specifically, in the fifth step, as illustrated in FIG. 9, the main surface 501 of the resin member 500 on an opposite side to the mounting substrate 2 side is polished by using the polishing machine such that a thickness of the resin member 500 in the thickness direction D1 of the mounting substrate 2 is reduced. Thus, tip portions of the plurality of metal members 700 are polished to form the plurality of first connection terminals 71, and the main surface 501 of the resin member 500 is polished to form the resin layer 5. By polishing a surface of the second electronic component 3B on an opposite side to the mounting substrate 2 side, it is possible to reduce a thickness of the second electronic component 3B in the thickness direction D1 of the mounting substrate 2.

Here, by executing the fifth step, a main surface 711 of each of the plurality of first connection terminals 71 on an opposite side to the mounting substrate 2 side, a main surface 31 of the second electronic component 3B on an opposite side to the mounting substrate 2 side, and the main surface 51 of the resin layer 5 on an opposite side to the mounting substrate 2 side are on the same plane (see FIG. 9). That is, in the thickness direction D1 of the mounting substrate 2, the distance (length) L1 of each of the plurality of first connection terminals 71, the distance L3 of the second electronic component 3B, and the distance L4 of the resin layer 5 are the same. The distance (length) L1 is a distance from the second main surface 22 of the mounting substrate 2 to the main surface 711 of the first connection terminal 71 on an opposite side to the mounting substrate 2 side. The distance L3 is a distance from the second main surface 22 of the mounting substrate 2 to the main surface 31 of the second electronic component 3B on an opposite side to the mounting substrate 2 side. The distance L4 is a distance from the second main surface 22 of the mounting substrate 2 to the main surface 51 of the resin layer 5 on an opposite side to the mounting substrate 2 side. In the state illustrated in FIG. 9, the main surface 711 of each of the plurality of first connection terminals 71 on an opposite side to the mounting substrate 2 side and the main surface 31 of the second electronic component 3B on an opposite side to the mounting substrate 2 side are respectively exposed. As described above, the main surface 711 of the plurality of first connection terminals 71, the main surface 31 of the second electronic component 3B, and the main surface 51 of the resin layer 5 are on the same plane, so that it is possible to improve coplanarity (flatness) of the second connection terminal 72 connected to the first connection terminal 71.

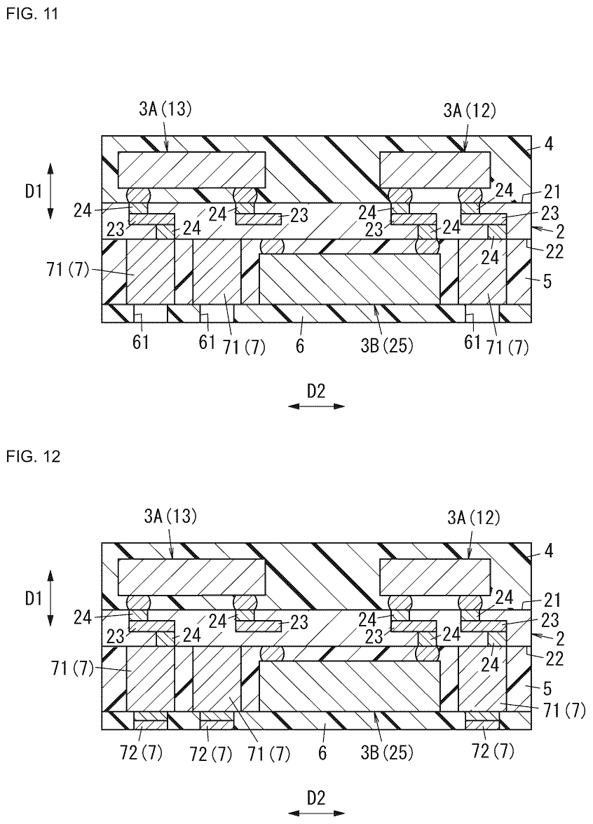

The sixth step is a step of forming a resin member 600 (second resin member). More specifically, in the sixth step, as illustrated in FIG. 10, the resin member 600 serving as a base of the resin layer 6 is formed on a side of the resin layer 5 opposite to the mounting substrate 2 side, in the thickness direction D1 of the mounting substrate 2. The seventh step is a step of forming a through-hole 61 in the resin member 600 to form the resin layer 6 (second resin layer). More specifically, in the seventh step, as illustrated in FIG. 11, the through-hole 61 is formed at a part of the resin member 600 facing the first connection terminal 71 in the thickness direction D1 of the mounting substrate 2. Thus, the resin layer 6 having the through-hole 61 is formed. A diameter of each through-hole 61 is the same as the diameter d2 of the second connection terminal 72, and smaller than the diameter d1 of the first connection terminal 71.

The eighth step is a step of forming the plurality of second connection terminals 72. More specifically, in the eighth step, as illustrated in FIG. 12, the second connection terminal 72 is formed in the through-hole 61 formed in the resin layer 6. Specifically, after the first layer 721 of the second connection terminal 72 is formed by growing nickel plating, the second layer 722 of the second connection terminal 72 is formed by growing gold plating. The ninth step is a step of forming the metal electrode layer 8 by, for example, a sputtering method, a evaporation method, or a printing method. More specifically, in the ninth step, as illustrated in FIG. 2, the metal electrode layer 8 is formed in contact with the main surface of the resin layer 4 on an opposite side to the mounting substrate 2 side, the outer peripheral surface of the resin layer 4, the outer peripheral surface of the mounting substrate 2, the outer peripheral surface of the resin layer 5, and the outer peripheral surface of the resin layer 6.

With the first to ninth steps described above, the radio frequency module 1 as illustrated in FIG. 2 can be manufactured. In the state illustrated in FIG. 2, the second connection terminal 72 is located inside the first connection terminal 71 in the plan view in the thickness direction D1 of the mounting substrate 2.

Meanwhile, as illustrated in FIG. 9, in the radio frequency module 1 according to Embodiment 1, the main surface 31 of the second electronic component 3B on an opposite side to the mounting substrate 2 side and the main surface 51 of the resin layer 5 on an opposite side to the mounting substrate 2 side are on the same plane. Further, in the radio frequency module 1 according to Embodiment 1, as illustrated in FIGS. 10 to 12, the outer peripheral surface of the second electronic component 3B is covered with the resin layer 5, and the main surface 31 (see FIG. 9) of the second electronic component 3B is covered with the resin layer 6. As described above, even in a case where the second electronic component 3B is covered with the resin layer 6, and for example, the resin layer 6 is cracked, the crack is generated up to an interface between the resin layer 5 and the resin layer 6, and thus, it is possible to protect the second electronic component 3B.

Further, in the radio frequency module 1 according to Embodiment 1, the first connection terminal 71 can be enlarged to the vicinity of the metal electrode layer 8 in the second direction D2, so that the characteristics of the radio frequency module 1 can be improved. On the other hand, the second connection terminal 72 is made smaller than the first connection terminal 71, so that a distance from the metal electrode layer 8 can be secured, and, as a result, the second connection terminal 72 and the metal electrode layer 8 are less likely to come into contact with each other (short circuit).

In the method of manufacturing the radio frequency module 1 according to Embodiment 1, the first step is a step of preparing the mounting substrate 2 having the first main surface 21 and the second main surface 22 facing each other. Further, in the method of manufacturing the radio frequency module 1 according to Embodiment 1, the second step is a step of forming the metal member 700 on the second main surface 22 of the mounting substrate 2. Further, in the method of manufacturing the radio frequency module 1 according to Embodiment 1, the third step is a step of disposing the second electronic component 3B (electronic component) on the second main surface 22 of the mounting substrate 2. Further, in the method of manufacturing the radio frequency module 1 according to Embodiment 1, the fourth step is a step of forming the resin member 500 (first resin member) on the second main surface 22 side of the mounting substrate 2 to cover at least a part of the second electronic component 3B. Further, in the method of manufacturing the radio frequency module 1 according to Embodiment 1, the fifth step is a step of forming the resin layer 5 (first resin layer) by polishing the main surface 501 of the resin member 500 on an opposite side to the mounting substrate 2 side such that the main surface 711 of the first connection terminal 71 formed from the metal member 700, on an opposite side to the mounting substrate 2 side is exposed. Further, in the method of manufacturing the radio frequency module 1 according to Embodiment 1, the sixth step is a step of forming the resin member 600 (second resin member) on a side of the resin layer 5 opposite to the mounting substrate 2 side. Further, in the method of manufacturing the radio frequency module 1 according to Embodiment 1, the seventh step is a step of forming the through-hole 61 at a part of the resin member 600 facing the first connection terminal 71 in the thickness direction D1 of the mounting substrate 2 to form the resin layer 6 (second resin layer). Further, in the method of manufacturing the radio frequency module 1 according to Embodiment 1, the eighth step is a step of forming the second connection terminal 72 in the through-hole 61 of the resin layer 6.

Here, in the method of manufacturing the radio frequency module 1 according to Embodiment 1, after the step of forming the metal member 700 on the second main surface 22 of the mounting substrate 2 is mounted, the step of disposing the second electronic component 3B on the second main surface 22 of the mounting substrate 2. Meanwhile, the order of the above two steps may be reversed. That is, after the step of disposing the second electronic component 3B on the second main surface 22 of the mounting substrate 2, the step of forming the metal member 700 on the second main surface 22 of the mounting substrate 2 may be executed.

### (8) Effects

In the radio frequency module 1 according to Embodiment 1, the first connection terminal 71 is disposed on the second main surface 22 of the mounting substrate 2, and the second connection terminal 72 is disposed on a side of the first connection terminal 71 opposite to the mounting substrate 2 side. In addition, the second connection terminal 72 is connected to the first connection terminal 71, and the second connection terminal 72 is located inside the first connection terminal 71, in the plan view in the thickness direction D1 of the mounting substrate 2. Thus, as compared with a case where the second connection terminal 72 is as thick as the first connection terminal 71 in the plan view in the thickness direction D1 of the mounting substrate 2, it is possible to reduce the interval G1 between two first connection terminals 71 adjacent to each other in a direction (second direction D2) intersecting with the thickness direction D1 of the mounting substrate 2, and as a result, reduction in size of the radio frequency module 1 can be achieved. Further, as compared with a case where the first connection terminal 71 is as thin as the second connection terminal 72 in the plan view in the thickness direction D1 of the mounting substrate 2, it is possible to reduce an electric resistance of the first connection terminal 71 and the second connection terminal 72, and as a result, it is possible to reduce a signal loss. That is, with the radio frequency module 1 according to Embodiment 1, it is possible to reduce the signal loss while achieving the reduction in size of the radio frequency module 1.

Further, in the radio frequency module 1 according to Embodiment 1, the interval G2 between two second connection terminals 72 adjacent to each other in the second direction D2 that intersects (orthogonal) with the first direction D1 which is a thickness direction of the mounting substrate 2 is larger than the interval G1 between two first connection terminals 71 adjacent to each other in the second direction D2. Thus, it is possible to reduce connection failures assuming the radio frequency module 1 is mounted on the external substrate, as compared with a case where the interval G2 is the same as the interval G1.

Further, in the radio frequency module 1 according to Embodiment 1, the length L2 of the second connection terminal 72 is smaller than the length L1 of the first connection terminal 71, in the thickness direction D1 of the mounting substrate 2. Thus, as compared with a case where the length L2 of the second connection terminal 72 is equal to or larger than the length L1 of the first connection terminal 71, an electric resistance can be reduced and a decrease in strength can be reduced.

Further, in the radio frequency module 1 according to Embodiment 1, each shape of the first connection terminal 71 and the second connection terminal 72 is cylindrical, and the diameter d1 of the first connection terminal 71 is larger than the diameter d2 of the second connection terminal 72 in the plan view in the thickness direction D1 of the mounting substrate 2. Thus, the electric resistance can be reduced as compared with a case where the diameter dl of the first connection terminal 71 is the same as the diameter d2 of the second connection terminal 72.

### (9) Modification Example

In the radio frequency module 1 according to Embodiment 1, as illustrated in FIG. 3A, the second connection terminal 72 has a two-layer structure including the first layer 721 and the second layer 722. Meanwhile, as illustrated in FIG. 3B, the second connection terminal 72 may have a three-layer structure including the first layer 721, the second layer 722, and a third layer 723. In this case, the first layer 721 is, for example, a copper plating layer. The second layer 722 is, for example, a nickel plating layer. The third layer 723 is a gold plating layer. In this case as well, the second connection terminal 72 is located inside the first connection terminal 71 in the plan view in the thickness direction D1 of the mounting substrate 2, so that it is possible to reduce a signal loss while achieving reduction in size of the radio frequency module 1.

Further, in the radio frequency module 1 according to Embodiment 1, the second connection terminal 72 has a two- layer structure or a three-layer structure, and may have, for example, a one-layer structure.

### Embodiment 2

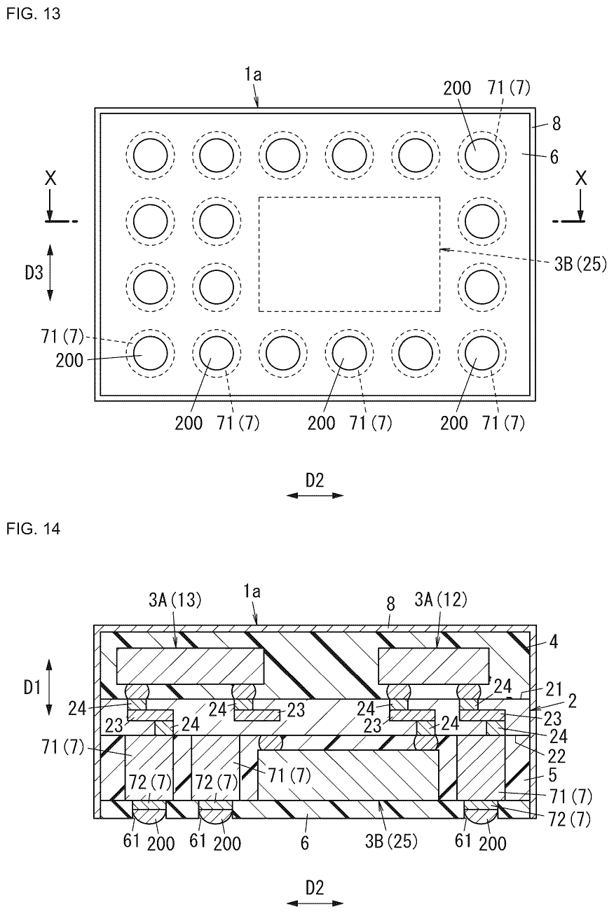

A radio frequency module 1a according to Embodiment 2 will be described with reference to FIGS. 13 and 14. Regarding the radio frequency module 1a according to Embodiment 2, the same configurations as the radio frequency module 1 according to Embodiment 1 (see FIG. 1 and FIG. 2) are attached with the same reference numerals, and the description thereof will be omitted.

As illustrated in FIG. 14, the radio frequency module 1a according to Embodiment 2 is different from the radio frequency module 1 (see FIGS. 1 and 2) according to Embodiment 1 in that a bump 200 is provided at a tip portion of each of the plurality of second connection terminals 72 (end portion on an opposite side to the first connection terminal 71 side).

### (1) Configuration

As illustrated in FIGS. 13 and 14, the radio frequency module 1a according to Embodiment 2 includes the mounting substrate 2, the plurality of (two in the illustrated example) first electronic components 3A, the second electronic component 3B, the plurality of first connection terminal 71, the plurality of second connection terminals 72, and a plurality of bumps 200. Further, the radio frequency module 1a according to Embodiment 2 further includes the plurality of (three in the illustrated example) resin layers 4 to 6 and the metal electrode layer 8. In FIG. 14, each of the plurality of second connection terminals 72 is illustrated as one layer, and actually has a two-layer structure including two layers. In addition, the plurality of first connection terminals 71, the plurality of second connection terminals 72, and the plurality of bumps 200 have a one-to-one correspondence.

Each of the plurality of second connection terminals 72 is formed in the corresponding through-hole 61 among the plurality of through-holes 61 of the resin layer 6 (second resin layer). Each of the plurality of bumps 200 is formed in the corresponding through-hole 61 among the plurality of through-holes 61 of the resin layer 6. Further, each of the plurality of bumps 200 is connected to the corresponding second connection terminal 72 among the plurality of second connection terminals 72, and has a tip portion on an opposite side to the second connection terminal 72, which is exposed from the corresponding through-hole 61. A material of the plurality of bumps 200 is, for example, a solder. The material of the plurality of bumps 200 is not limited to the solder, and may be, for example, gold or copper.

In the radio frequency module 1a according to Embodiment 2, as illustrated in FIG. 14, the bump 200 is disposed on a side of the second connection terminal 72 opposite to the first connection terminal 71 side. In addition, the bump 200 is located inside the first connection terminal 71 in the plan view in the thickness direction D1 of the mounting substrate 2 (see FIG. 13).

### (2) Effects

In the radio frequency module 1a according to Embodiment 2, the second connection terminal 72 and the bump 200 are located inside the first connection terminal 71 in the plan view in the thickness direction D1 of the mounting substrate 2. Thus, in the same manner as the radio frequency module 1 according to Embodiment 1, it is possible to reduce the signal loss while achieving the reduction in size of the radio frequency module la.

### (3) Modification Example

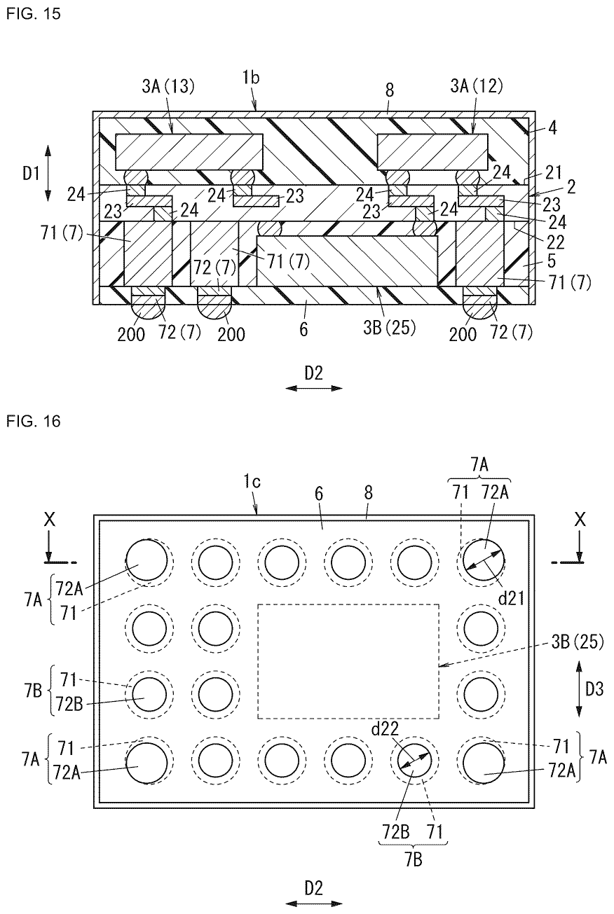

In Embodiment 2, a part of the bump 200 is exposed from the through-hole 61. Meanwhile, for example, an entirety of the bump 200 may be exposed from the through-hole 61, as in a radio frequency module 1b illustrated in FIG. 15. In this case as well, the second connection terminal 72 and the bump 200 are located inside the first connection terminal 71 in the plan view in the thickness direction D1 of the mounting substrate 2, so that it is possible to reduce the signal loss while achieving the reduction in size of the radio frequency module 1b.

### Embodiment 3

A radio frequency module 1c according to Embodiment 3 will be described with reference to FIG. 16. Regarding the radio frequency module 1c according to Embodiment 3, the same configurations as the radio frequency module 1 according to Embodiment 1 (see FIG. 1 and FIG. 2) are attached with the same reference numerals, and the description thereof will be omitted.

As illustrated in FIG. 16, the radio frequency module 1c according to Embodiment 3 is different from the radio frequency module 1 (see FIGS. 1 and 2) according to Embodiment 1 in that a diameter d21 of four second connection terminals 72A disposed at four corners of the mounting substrate 2 (see FIG. 2) among the plurality of second connection terminals 72 is larger than a diameter d22 of remaining second connection terminals 72B.

### (1) Configuration

As illustrated in FIG. 16, the radio frequency module 1c according to Embodiment 3 includes the mounting substrate 2 (see FIG. 2), the plurality of first electronic components 3A (see FIG. 2), the second electronic component 3B (see FIG. 2), the plurality of first connection terminals 71, and a plurality of second connection terminals 72A and 72B. Further, the radio frequency module 1c according to Embodiment 3 further includes the plurality of resin layers 4 to 6 (see FIG. 2) and the metal electrode layer 8.

Each of the plurality of second connection terminals 72A and 72B is located inside the corresponding first connection terminal 71 among the plurality of first connection terminals 71, in the plan view in the thickness direction D1 of the mounting substrate 2. A part of an outer edge of each of the four second connection terminals 72A disposed at the four corners of the mounting substrate 2 among the plurality of second connection terminals 72A and 72B overlaps with an outer edge of the corresponding first connection terminal 71 in the plan view in the thickness direction D1 of the mounting substrate 2. On the other hand, an outer edge of each of the remaining second connection terminals 72B does not overlap with an outer edge of the corresponding first connection terminal 71 in the plan view in the thickness direction D1 of the mounting substrate 2.

More specifically, the part of the outer edge of each of the plurality of second connection terminals 72A overlaps with a part of the outer edge of the corresponding first connection terminal 71 at a portion near the four corners of the mounting substrate 2. For example, a part of an outer edge of the second connection terminal 72A at the upper left in FIG. 16 overlaps with an upper left portion of an outer edge of the corresponding first connection terminal 71, and a part of an outer edge of the second connection terminal 72A at the upper right in FIG. 16 overlaps with an upper right portion of an outer edge of the corresponding first connection terminal 71. In addition, a part of an outer edge of the second connection terminal 72A at the lower left in FIG. 16 overlaps with a lower left portion of an outer edge of the corresponding first connection terminal 71, and a part of an outer edge of the second connection terminal 72A at the lower right in FIG. 16 overlaps with a lower right portion of an outer edge of the corresponding first connection terminal 71.

Further, the diameter d21 of each of the four second connection terminals 72A is larger than the diameter d22 of each of the remaining second connection terminals 72B. Here, in a case where an external force is applied to the radio frequency module 1c, stress applied to the four second connection terminals 72A disposed at the four corners of the mounting substrate 2 becomes the largest. Therefore, by increasing the diameter d21 of the four second connection terminals 72A, it is possible to improve connection reliability with the external substrate (not illustrated). On the other hand, regarding the remaining second connection terminals 72B, the second connection terminal 72A or the second connection terminal 72B is disposed on both sides in the second direction D2 or a third direction D3, so that it is possible to reduce short-circuit between the terminals by reducing the diameter d22. Here, the second direction D2 is a direction that intersects (orthogonal) with the first direction D1 which is a thickness direction of the mounting substrate 2 and is a longitudinal direction of the mounting substrate 2. In addition, the third direction D3 is a direction orthogonal to both the first direction D1 and the second direction D2, and is a short direction of the mounting substrate 2.

The second connection terminals 72A are not limited to being disposed at all the four corners of the mounting substrate 2, and the second connection terminals 72A may be disposed at one to three corners of the four corners of the mounting substrate 2.

### (2) Effects

In the radio frequency module 1c according to Embodiment 3, the second connection terminals 72A and 72B are located inside the first connection terminal 71 in the plan view in the thickness direction D1 of the mounting substrate 2. Thus, in the same manner as the radio frequency module 1 according to Embodiment 1, it is possible to reduce the signal loss while achieving the reduction in size of the radio frequency module 1c.

### Embodiment 4

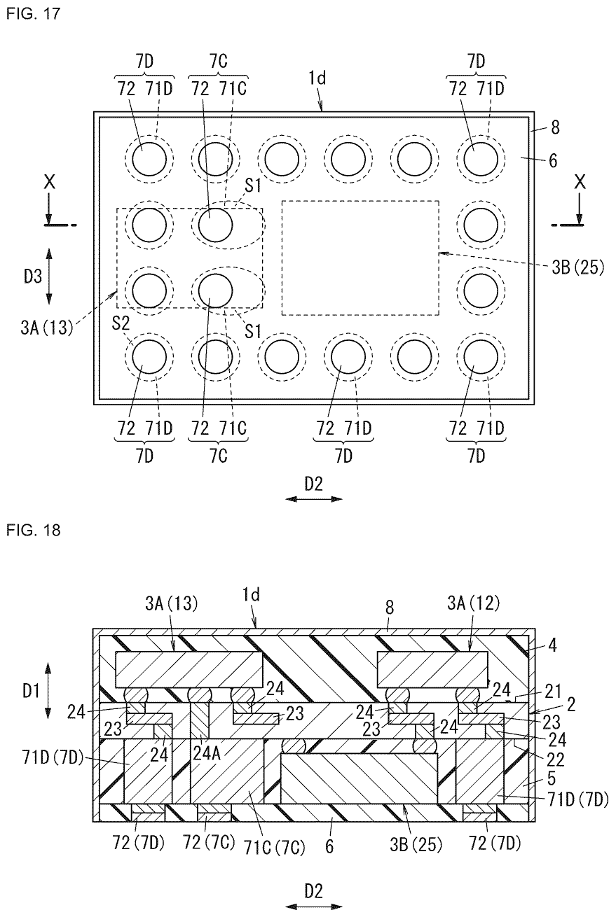

A radio frequency module 1d according to Embodiment 4 will be described with reference to FIGS. 17 and 18. Regarding the radio frequency module 1d according to Embodiment 4, the same configurations as the radio frequency module 1 according to Embodiment 1 (see FIG. 1 and FIG. 2) are attached with the same reference numerals, and the description thereof will be omitted.

As illustrated in FIGS. 17 and 18, the radio frequency module 1d according to Embodiment 4 is different from the radio frequency module 1 (see FIGS. 1 and 2) according to Embodiment 1 in that an area S1 of two first connection terminals 71C overlapping with one (left side in FIG. 18) of the first electronic components 3A in the thickness direction D1 of the mounting substrate 2 among a plurality of first connection terminals 71C and 71D is larger than an area S2 of remaining first connection terminals 71D.

### (1) Configuration

As illustrated in FIGS. 17 and 18, the radio frequency module 1d according to Embodiment 4 includes the mounting substrate 2, the plurality of first electronic components 3A, the second electronic component 3B, a plurality of first connection terminals 71C and 71D, and the plurality of second connection terminals 72. Further, the radio frequency module 1d according to Embodiment 4 further includes the plurality of resin layers 4 to 6 and the metal electrode layer 8.

As illustrated in FIG. 17, two first connection terminals 71C and two first connection terminals 71D among the plurality of first connection terminals 71C and 71D overlap with the first electronic component 3A in the thickness direction D1 of the mounting substrate 2. Each of the two first connection terminals 71C that overlap with the first electronic component 3A in the thickness direction D1 of the mounting substrate 2 among the plurality of first connection terminals 71C and 71D has an elliptical shape that is long in the second direction D2 in the plan view in the thickness direction D1 of the mounting substrate 2. On the other hand, each of the remaining first connection terminals 71D has a circular shape in the plan view in the thickness direction D1 of the mounting substrate 2. In addition, in the plan view in the thickness direction D1 of the mounting substrate 2, the area S1 of each of the two first connection terminals 71C is larger than the area S2 of each of the remaining first connection terminals 71D.

Here, as illustrated in FIG. 18, each of the two first connection terminals 71C is connected to a heat radiation terminal of one (left side in FIG. 18) of the first electronic components 3A with a via-conductor 24A interposed therebetween, which passes through the mounting substrate 2 in the thickness direction D1 of the mounting substrate 2. The first electronic component 3A is, for example, an electronic component constituting the power amplifier 13. In the radio frequency module 1d according to Embodiment 4, heat generated in the first electronic component 3A constituting the power amplifier 13 can be radiated to the external substrate (not illustrated) with the via-conductor 24A and the two first connection terminals 71C interposed therebetween.

### (2) Effects

In the radio frequency module 1d according to Embodiment 4, the second connection terminal 72 is located inside the first connection terminals 71C and 71D in the plan view in the thickness direction D1 of the mounting substrate 2 (see FIG. 17). Thus, in the same manner as the radio frequency module 1 according to Embodiment 1, it is possible to reduce the signal loss while achieving the reduction in size of the radio frequency module 1d.

Further, in the radio frequency module 1d according to Embodiment 4, the area S1 of the two first connection terminals 71C overlapping with the first electronic component 3A in the thickness direction D1 of the mounting substrate 2, among the plurality of first connection terminals 71C and 71D, is larger than the area S2 of the remaining first connection terminal 71D. Therefore, by connecting the first connection terminal 71C to the first electronic component 3A having the large amount of radiation heat, it is possible to improve heat radiation performance of the first electronic component 3A.

### (3) Modification Example

In Embodiment 4, the first connection terminal 71C is connected to the heat radiation terminal of the first electronic component 3A. Meanwhile, the first connection terminal 71C may be connected to, for example, a signal terminal of the first electronic component 3A. Thus, it is possible to reduce a signal loss, and, as a result, it is possible to reduce a characteristic deterioration of the radio frequency module 1d.

### Embodiment 5

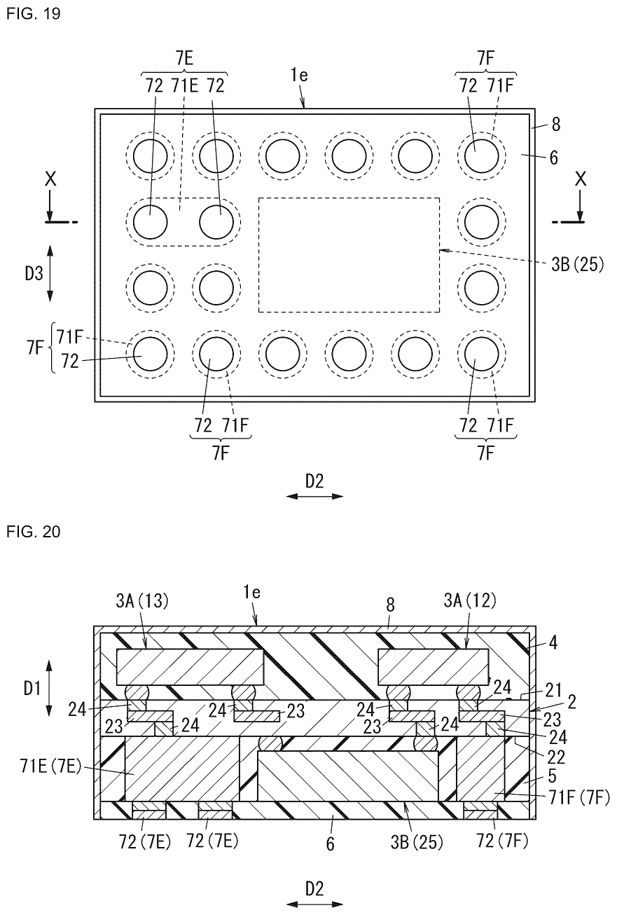

A radio frequency module 1e according to Embodiment 5 will be described with reference to FIGS. 19 and 20. Regarding the radio frequency module 1e according to Embodiment 5, the same configurations as the radio frequency module 1 according to Embodiment 1 (see FIG. 1 and FIG. 2) are attached with the same reference numerals, and the description thereof will be omitted.

As illustrated in FIGS. 19 and 20, the radio frequency module 1e according to Embodiment 5 is different from the radio frequency module 1 (see FIG. 1 and FIG. 2) according to Embodiment 1 in that a first connection terminal 71E has an elliptical shape in the plan view in the thickness direction D1 of the mounting substrate 2. Further, the radio frequency module 1e according to Embodiment 5 is different from the radio frequency module 1 according to Embodiment 1 in that two second connection terminals 72 are connected to one first connection terminal 71E.

### (1) Configuration

As illustrated in FIGS. 19 and 20, the radio frequency module 1e according to Embodiment 5 includes the mounting substrate 2, the plurality of first electronic components 3A, the second electronic component 3B, a plurality of first connection terminals 71E and 71F, and the plurality of second connection terminals 72. Further, the radio frequency module le according to Embodiment 5 further includes the plurality of resin layers 4 to 6 and the metal electrode layer 8.

As illustrated in FIG. 19, the first connection terminal 71E, which is one of the plurality of first connection terminals 71E and 71F, has an elliptical shape that is long in the second direction D2, in the plan view in the thickness direction D1 of the mounting substrate 2. On the other hand, each of the remaining first connection terminals 71F has a circular shape in the plan view in the thickness direction D1 of the mounting substrate 2. As illustrated in FIG. 19, the two second connection terminals 72 are connected to the first connection terminal 71E.

Here, as illustrated in FIG. 20, the first connection terminal 71E is connected to the signal terminal of the first electronic component 3A with the conductive layer 23 and the via-conductor 24 included in the mounting substrate 2 therebetween. The first electronic component 3A is, for example, an electronic component constituting the power amplifier 13. Therefore, by enlarging the first connection terminal 71E connected to the first electronic component 3A and by connecting the two second connection terminals 72 to the first connection terminal 71E, it is possible to reduce a signal loss, and as a result, it is possible to reduce a characteristic deterioration of the radio frequency module 1e.

### (2) Effects

In the radio frequency module 1e according to Embodiment 5, the second connection terminal 72 is located inside the first connection terminals 71E and 71F in the plan view in the thickness direction D1 of the mounting substrate 2 (see FIG. 19). Thus, in the same manner as the radio frequency module 1 according to Embodiment 1, it is possible to reduce the signal loss while achieving the reduction in size of the radio frequency module 1e.

Further, in the radio frequency module 1e according to Embodiment 5, the first connection terminal 71E has an elliptical shape in the plan view in the thickness direction D1 of the mounting substrate 2, and the two second connection terminals 72 are connected to the first connection terminal 71E. In addition, in the radio frequency module 1e according to Embodiment 5, the first connection terminal 71E is connected to the signal terminal of the first electronic component 3A. Thus, it is possible to reduce a signal loss, and, as a result, it is possible to reduce a characteristic deterioration of the radio frequency module 1e.

### (3) Modification Example

In Embodiment 5, the first connection terminal 71E is connected to the signal terminal of the first electronic component 3A. Meanwhile, the first connection terminal 71E may be connected to, for example, the heat radiation terminal of the first electronic component 3A. Thus, heat generated in the first electronic component 3A can be radiated to the external substrate (not illustrated) with the first connection terminal 71E and the two second connection terminals 72E interposed therebetween.

In Embodiment 5, the two second connection terminals 72 are connected to one first connection terminal 71E. Meanwhile, three or more second connection terminals 72 may be connected to one first connection terminal 71E. In short, two or more second connection terminals 72 may be connected to one first connection terminal 71E.

In a case where three or more second connection terminals 72 are connected to one first connection terminal 71, the three or more second connection terminals 72 may be arranged side by side in a line or may be arranged on a plane.

The first connection terminal 71E is not limited to the elliptical shape in the plan view in the thickness direction D1 of the mounting substrate 2, and may have a shape other than the elliptical shape.

### Embodiment 6

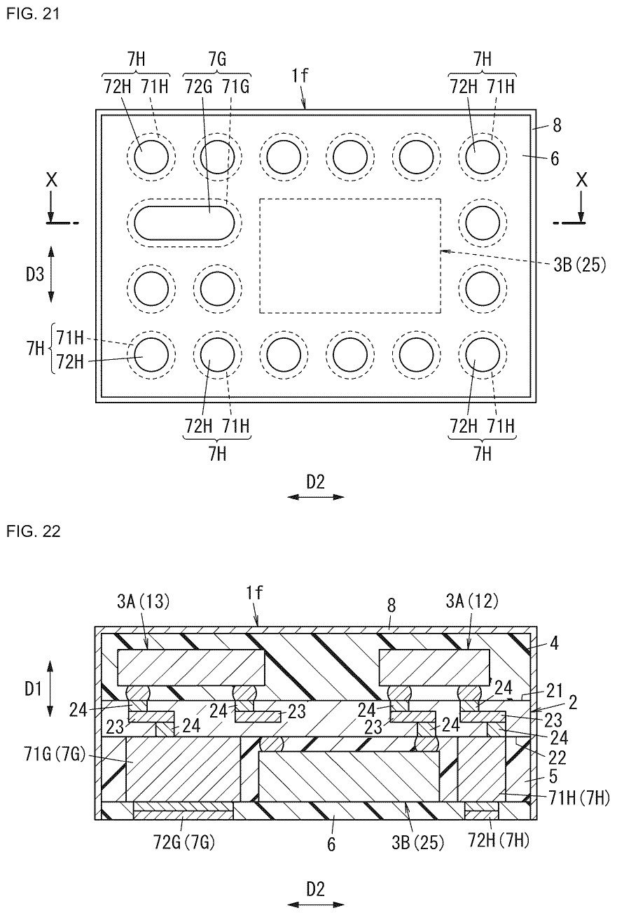

A radio frequency module 1f according to Embodiment 6 will be described with reference to FIGS. 21 and 22. Regarding the radio frequency module 1f according to Embodiment 6, the same configurations as the radio frequency module 1e according to Embodiment 5 (see FIG. 19 and FIG. 20) are attached with the same reference numerals, and the description thereof will be omitted.

As illustrated in FIGS. 21 and 22, the radio frequency module 1f according to Embodiment 6 is different from the radio frequency module 1e (see FIG. 19 and FIG. 20) according to Embodiment 5 in that a second connection terminal 72G has an elliptical shape in the plan view in the thickness direction D1 of the mounting substrate 2.

### (1) Configuration

As illustrated in FIGS. 21 and 22, the radio frequency module 1f according to Embodiment 6 includes the mounting substrate 2, the plurality of first electronic components 3A, the second electronic component 3B, a plurality of first connection terminals 71G and 71H, and a plurality of second connection terminals 72G and 72H. Further, the radio frequency module 1f according to Embodiment 6 further includes the plurality of resin layers 4 to 6 and the metal electrode layer 8.

As illustrated in FIG. 21, the first connection terminal 71G, which is one of the plurality of first connection terminals 71G and 71H, has an elliptical shape that is long in the second direction D2, in the plan view in the thickness direction D1 of the mounting substrate 2. On the other hand, each of the remaining first connection terminals 71H has a circular shape in the plan view in the thickness direction D1 of the mounting substrate 2. Further, as illustrated in FIG. 21, the second connection terminal 72G, which is one of the plurality of second connection terminals 72G and 72H, has an elliptical shape that is long in the second direction D2, in the plan view in the thickness direction D1 of the mounting substrate 2. On the other hand, each of the remaining second connection terminals 72H has a circular shape in the plan view in the thickness direction D1 of the mounting substrate 2. As illustrated in FIG. 21, the second connection terminal 72G is connected to the first connection terminal 71G, and the second connection terminal 72H is connected to the first connection terminal 71H. Further, as illustrated in FIG. 21, the second connection terminal 72G is located inside the first connection terminal 71G, and the second connection terminal 72H is located inside the first connection terminal 71H in the plan view in the thickness direction D1 of the mounting substrate 2.

Here, as illustrated in FIG. 22, the first connection terminal 71G is connected to the signal terminal of the first electronic component 3A with the conductive layer 23 and the via-conductor 24 included in the mounting substrate 2 therebetween. The first electronic component 3A is an electronic component constituting the power amplifier 13. Therefore, by enlarging each of the first connection terminal 71G and the second connection terminal 72G connected to the first electronic component 3A, it is possible to reduce a signal loss, and, as a result, it is possible to reduce a characteristic deterioration of the radio frequency module 1f.

### (2) Effects

In the radio frequency module 1f according to Embodiment 6, the second connection terminals 72G and 72H are located inside the first connection terminals 71G and 71H in the plan view in the thickness direction D1 of the mounting substrate 2 (see FIG. 21). Thus, in the same manner as the radio frequency module 1 according to Embodiment 1, it is possible to reduce the signal loss while achieving the reduction in size of the radio frequency module 1f.

Further, in the radio frequency module 1f according to Embodiment 6, each of the first connection terminal 71G and the second connection terminal 72G connected to the first connection terminal 71G has an elliptical shape in the plan view in the thickness direction D1 of the mounting substrate 2. In the radio frequency module 1f according to Embodiment 6, the first connection terminal 71G is connected to the signal terminal of the first electronic component 3A. Thus, it is possible to reduce a signal loss, and, as a result, it is possible to reduce a characteristic deterioration of the radio frequency module 1f.

### (3) Modification Example

In Embodiment 6, the first connection terminal 71G is connected to the signal terminal of the first electronic component 3A. Meanwhile, the first connection terminal 71G may be connected to, for example, the heat radiation terminal of the first electronic component 3A. Thus, heat generated in the first electronic component 3A can be radiated to the external substrate (not illustrated) with the first connection terminal 71G and the second connection terminal 72G interposed therebetween.

### Embodiment 7

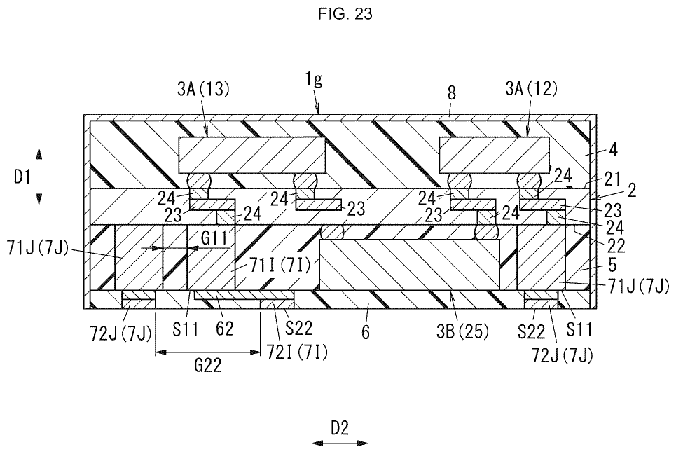

A radio frequency module 1g according to Embodiment 7 will be described with reference to FIG. 23. Regarding the radio frequency module 1g according to Embodiment 7, the same configurations as the radio frequency module 1 according to Embodiment 1 (see FIG. 1 and FIG. 2) are attached with the same reference numerals, and the description thereof will be omitted.

As illustrated in FIG. 23, the radio frequency module 1g according to Embodiment 7 is different from the radio frequency module 1 according to Embodiment 1 (see FIGS. 1 and 2) in that a first connection terminal 71I and a second connection terminal 72I are connected to each other with a conductive layer 62 interposed therebetween.

### (1) Configuration

As illustrated in FIG. 23, the radio frequency module 1g according to Embodiment 7 includes the mounting substrate 2, the plurality of first electronic components 3A, the second electronic component 3B, a plurality of first connection terminals 71I and 71J, and a plurality of second connection terminals 72I and 72J. Further, the radio frequency module 1g according to Embodiment 7 further includes the plurality of resin layers 4 to 6 and the metal electrode layer 8.

A shape of each of the plurality of first connection terminals 71I and 71J is a columnar shape (for example, a cylindrical shape). Further, a shape of each of the plurality of second connection terminals 721 and 72J is a columnar shape (for example, a cylindrical shape). In addition, in the plan view in the thickness direction D1 of the mounting substrate 2, an area S11 of each of the plurality of first connection terminals 71I and 71J is larger than an area S22 of each of the plurality of second connection terminals 721 and 72J. Further, the first connection terminal 711, which is one of the plurality of first connection terminals 711 and 71J, and the second connection terminal 721, which is one of the plurality of second connection terminals 721 and 72J, are connected to each other along the second direction D2 with the long conductive layer 62 interposed therebetween. That is, in the radio frequency module 1g according to Embodiment 7, the first connection terminal 711 and the second connection terminal 72I are not directly connected. Further, in the radio frequency module 1g according to Embodiment 7, as illustrated in FIG. 23, the first connection terminal 711 and the second connection terminal 72I do not overlap with each other, in the plan view in the thickness direction D1 of the mounting substrate 2.

### (2) Effects

In the radio frequency module 1g according to Embodiment 7, the area S11 of the first connection terminal 71I is larger than the area S22 of the second connection terminal 72I, in the plan view in the thickness direction D1 of the mounting substrate 2. In addition, the area S11 of the first connection terminal 71J is larger than the area S22 of the second connection terminal 72J, in the plan view in the thickness direction D1 of the mounting substrate 2. Thus, as compared with a case where the second connection terminals 721 and 72J are as thick as the first connection terminals 71I and 71J in the plan view in the thickness direction D1 of the mounting substrate 2, it is possible to reduce an interval G11 between two first connection terminals 71I and 71J adjacent to each other in a direction (second direction D2) intersecting with the thickness direction D1 of the mounting substrate 2, and as a result, reduction in size of the radio frequency module 1g can be achieved. Further, as compared with a case where the first connection terminals 71I and 71J are as thin as the second connection terminals 721 and 72J in the plan view in the thickness direction D1 of the mounting substrate 2, it is possible to reduce an electric resistance of the first connection terminals 711 and 71J and the second connection terminals 72I and 72J, and as a result, it is possible to reduce a signal loss. That is, with the radio frequency module 1g according to Embodiment 7, it is possible to reduce a signal loss while achieving reduction in size of the radio frequency module 1g.

Further, in the radio frequency module 1g according to Embodiment 7, an interval G22 between the two second connection terminals 721 and 72J adjacent to each other in the second direction D2 is larger than the interval G2 between the two second connection terminals 72 described in Embodiment 1. Thus, as compared with the radio frequency module 1 according to Embodiment 1, it is possible to further reduce connection failures assuming the radio frequency module 1g is mounted on the external substrate (not illustrated).

### Modification Examples

Hereinafter, Modification Examples of Embodiments 1 to 7 will be described.

The radio frequency modules 1, 1a, 1b, 1c, 1d, 1e, 1f, and 1g according to Embodiments 1 to 7 include the metal electrode layer 8. Meanwhile, the metal electrode layer 8 may be omitted.

In the radio frequency modules 1, 1a, 1b, 1c, 1d, 1e, 1f, and 1g according to Embodiments 1 to 7, the material of the resin layer 5 and the material of the resin layer 6 are different from each other. Meanwhile, the material of the resin layer 5 may be the same as the material of the resin layer 6. In this case, since a coefficient of linear expansion of the resin layer 5 and a coefficient of linear expansion of the resin layer 6 are the same, separating is less likely to occur between the resin layer 5 and the resin layer 6.

In the radio frequency module 1 according to Embodiment 1, the material of the first connection terminal 71 and the material of the second connection terminal 72 are different from each other. Meanwhile, the material of the first connection terminal 71 and the material of the second connection terminal 72 may be the same. Thus, a bonding strength between the first connection terminal 71 and the second connection terminal 72 can be increased, as compared with a case where the material of the first connection terminal 71 and the material of the second connection terminal 72 are different from each other. The same applies to the radio frequency modules 1a, 1b, 1c, 1d, 1e, 1f, and 1g according to Embodiments 2 to 7.

In the radio frequency module 1 according to Embodiment 1, the copper plating layer grown from the second main surface 22 of the mounting substrate 2 is used as the first connection terminal 71. For example, a solder layer formed at the second main surface 22 of the mounting substrate 2 may be used as the first connection terminal 71, or a pillar (for example, a copper pillar) mounted on the second main surface 22 of the mounting substrate 2 may be used as the first connection terminal 71. The same applies to the radio frequency modules 1a, 1b, 1c, 1d, 1e, 1f, and 1g according to Embodiments 2 to 7.

In the radio frequency module 1 according to Embodiment 1, the plating layer grown from the main surface 711 of the first connection terminal 71 on an opposite side to the mounting substrate 2 side is used as the second connection terminal 72. For example, the second connection terminal 72 may be formed by printing on the main surface 711 of the first connection terminal 71. The same applies to the radio frequency modules 1a, 1b, 1c, 1d, 1e, 1f, and 1g according to Embodiments 2 to 7.

Each of the transmission filter 11 and the reception filter 12 according to Embodiments 1 to 7 is not limited to a ladder filter, and may be, for example, a longitudinally coupled resonator-type surface acoustic wave filter.

In addition, the acoustic wave filter described above is an acoustic wave filter that uses a surface acoustic wave or a bulk acoustic wave, and is not limited thereto. For example, an acoustic wave filter that uses a boundary acoustic wave, a plate wave, or the like may be used.

Further, the communication device 100 according to Embodiment 1 may include any one of the radio frequency modules 1a, 1b, 1c, 1d, 1e, 1f, and 1g, instead of the radio frequency module 1.

In the present specification, “an element is disposed on a first main surface of a substrate” includes both a case where the element is directly mounted on the first main surface of the substrate and a case where the element is disposed in a space on the first main surface side between the space on the first main surface side and a space on the second main surface side separated by the substrate. That is, “the element is disposed on the first main surface of the substrate” includes a case where the element is mounted on the first main surface of the substrate with another circuit element, an electrode, or the like interposed therebetween. The element is, for example, the first electronic component 3A, and is not limited to the first electronic component 3A. The substrate is, for example, the mounting substrate 2. In a case where the substrate is the mounting substrate 2, the first main surface is the first main surface 21 and the second main surface is the second main surface 22.

In the present specification, “an element is disposed on a second main surface of a substrate” includes both a case where the element is directly mounted on the second main surface of the substrate and a case where the element is disposed in a space on the second main surface side between the space on the first main surface side and a space on the second main surface side separated by the substrate. That is, “the element is disposed on the second main surface of the substrate” includes a case where the element is mounted on the second main surface of the substrate with another circuit element, an electrode, or the like interposed therebetween. The element is, for example, the second electronic component 3B, and is not limited to the second electronic component 3B. The substrate is, for example, the mounting substrate 2. In a case where the substrate is the mounting substrate 2, the first main surface is the first main surface 21 and the second main surface is the second main surface 22.

In the present specification, “A is located inside B” means that a first region determined by an outer edge of B is included in a second region determined by an outer edge of A and the first region is smaller than the second region. A is, for example, the first connection terminal 71 in the plan view in the thickness direction D1 of the mounting substrate 2. B is, for example, the second connection terminal 72 in the plan view in the thickness direction D1 of the mounting substrate 2.

### Aspects

The following aspects are disclosed in the present specification.

According to a first aspect, there is provided a radio frequency module (1; 1a to 1f) includes a mounting substrate (2), a first electronic component (3A), a second electronic component (3B) and a first connection terminal (71; 71C to 71H), a second connection terminal (72; 72A, 72B; 72G, 72H), a first resin layer (5), and a second resin layer (6). The mounting substrate (2) has a first main surface (21) and a second main surface (22) facing each other. The first electronic component (3A) is disposed on the first main surface (21) of the mounting substrate (2). The second electronic component (3B) and the first connection terminal (71; 71C to 71H) are disposed on the second main surface (22) of the mounting substrate (2). The second connection terminal (72; 72A, 72B; 72G, 72H) is connected to the first connection terminal (71; 71C to 71H), and is disposed on a side of the first connection terminal (71; 71C to 71H) opposite to the mounting substrate (2) side. The first resin layer (5) covers at least a part of the second electronic component (3B), and covers at least a part of the first connection terminals (71; 71C to 71H). The second resin layer (6) is disposed on the first resin layer (5), and covers at least a part of the second connection terminals (72; 72A, 72B; 72G, 72H). The second connection terminal (72; 71A, 71B; 71G, 71H) is located inside the first connection terminal (71; 71C to 71H) in a plan view from a thickness direction (D1) of the mounting substrate (2).

In the radio frequency module (1; 1a to 1f) according to the first aspect, the first connection terminal (71; 71C to 71H) is disposed on the second main surface (22) of the mounting substrate (2), and the second connection terminal (72; 72A, 72B; 72G, 72H) is disposed on a side of the first connection terminal (71; 71C to 71H) opposite to the mounting substrate (2) side. In addition, the second connection terminal (72) is connected to the first connection terminal (71; 71C to 71H), and the second connection terminal (72; 72A, 72B; 72G, 72H) is located inside the first connection terminal (71; 71C to 71H) in a plan view in the thickness direction (D1) of the mounting substrate (2). Thus, as compared with a case where the second connection terminal (72; 72A, 72B; 72G, 72H) has the same size as the first connection terminal (71; 71C to 71H) in the plan view in the thickness direction (D1) of the mounting substrate (2), it is possible to reduce an interval (G1) between two adjacent first connection terminals (71; 71C to 71H) in a direction (second direction D2) intersecting the thickness direction (D1) of the mounting substrate (2), as a result, reduction in size of the radio frequency module (1; 1a to 1f) can be achieved. Further, as compared with a case where the first connection terminal (71; 71C to 71H) has the same size as the second connection terminal (72; 72A, 72B; 72G, 72H) in the plan view in the thickness direction (D1) of the mounting substrate (2), an electric resistances of the first connection terminal (71; 71C to 71H) and the second connection terminal (72; 72A, 72B; 72G, 72H) can be reduced, and, as a result, an increase in signal loss can be reduced. That is, with this aspect, it is possible to reduce the increase in signal loss while achieving the reduction in size of the radio frequency module (1; 1a to 1f).

According to the first aspect, the radio frequency module (1; 1a to 1d) according to a second aspect includes a plurality of first connection terminals (71; 71C, 71D), and includes a plurality of second connection terminals (72; 72A, 72B). An interval (G2) between two second connection terminals (72; 72A, 72B) adjacent to each other in a second direction (D2) among the plurality of second connection terminal (72; 72A, 72B) is larger than the interval (G1) between two first connection terminals (71C, 71D) adjacent to each other in the second direction (D2) among the plurality of first connection terminals (71; 71C, 71D). The second direction (D2) is a direction that intersects with the first direction (D1) which is a thickness direction of the mounting substrate (2).

With this aspect, as compared with a case where the interval (G1) between the two first connection terminals (71; 71C, 71D) is the same as the interval (G2) between the two second connection terminals (72; 72A, 72B), it is possible to reduce connection failures based on mounting on an external substrate.

According to the first or second aspect, in the radio frequency module (1; 1a to 1f) according to a third aspect, a length (L2) of the second connection terminal (72; 72A, 72B, 72G, 72H) is smaller than a length (L1) of the first connection terminal (71; 71C to 71H), in the thickness direction (D1) of the mounting substrate (2).

With this aspect, as compared with a case where the length (L2) of the second connection terminal (72; 72A, 72B; 72G, 72H) is equal to or larger than the length (L1) of the first connection terminal (71; 71C to 71H), a terminal strength can be improved.

According to any one of the first to third aspects, in the radio frequency module (1; 1a to 1f) according to a fourth aspect, a material of the first connection terminal (71; 71C to 71H) includes copper. A material of the second connection terminal (72; 72A, 72B; 72G, 72H) includes gold.

With this aspect, it is possible to improve adhesion with a solder, as compared with a case where the material of the second connection terminal (72; 72A, 72B; 72G, 72H) includes copper but does not include gold.

According to any one of the first to third aspects, in the radio frequency module (1; 1a to 1f) according to a fifth aspect, a material of the first connection terminal (71; 71C to 71H) is the same as a material of the second connection terminal (72; 72A, 72B; 72G, 72H).

With this aspect, as compared with a case where the material of the first connection terminal (1; 1a to 1f) and the material of the second connection terminal (72; 72A, 72B; 72G, 72H) are different from each other, it is possible to increase a bonding strength between the first connection terminal (1; 1a to 1f) and the second connection terminal (72; 72A, 72B; 72G, 72H).

According to any one of the first to fifth aspects, in the radio frequency module (1; 1a to 1f) according to a sixth aspect, a shape of each of the first connection terminal (71; 71C to 71H) and the second connection terminal (72; 72A, 72B; 72G, 72H) is a columnar shape. In the plan view in the thickness direction (D1) of the mounting substrate (2), an area (S1) of the first connection terminal (71; 71C to 71H) is larger than an area (S2) of the second connection terminal (72; 72A, 72B; 72G, 72H).

With this aspect, as compared with a case where the area (S1) of the first connection terminal (71; 71C to 71H) is the same as the area (S2) of the second connection terminal (72; 72A, 72B; 72G, 72H), it is possible to reduce an electric resistance.

According to any one of the first to sixth aspects, in the radio frequency module (1; 1a to 1d) according to a seventh aspect, a shape of each of the first connection terminal (71; 71C, 71D) and the second connection terminal (72; 72A, 72B) is a cylindrical shape. In the plan view in the thickness direction (D1) of the mounting substrate (2), a diameter (d1) of the first connection terminal (71; 71C, 71D) is larger than a diameter (d2) of the second connection terminal (72; 72A, 72B).

With this aspect, the electric resistance can be reduced, as compared with a case where the diameter (d1) of the first connection terminal (71; 71C, 71D) is the same as the diameter (d2) of the second connection terminal (72; 72A, 72B).

According to any one of the first to seventh aspects, in the radio frequency module (1; 1a to 1f) according to an eighth aspect, a main surface (31), a main surface (711), and a main surface (51) have the same distances (L1, L3, L4) from the second main surface (22) of the mounting substrate (2) in the thickness direction (D1) of the mounting substrate (2). The main surface (31) is a main surface of the second electronic component (3B) on an opposite side to the mounting substrate (2) side. The main surface (711) is a main surface of the first connection terminal (71; 71C to 71H) on an opposite side to the mounting substrate (2) side. The main surface (51) is a main surface of the first resin layer (5) on an opposite side to the mounting substrate (2) side.

With this aspect, the radio frequency module (1; 1a to 1f) can be reduced in size in the thickness direction (D1) of the mounting substrate (2).

According to any one of the first to eighth aspects, in the radio frequency module (1; 1a to 1f) according to a ninth aspect, a material of the first resin layer (5) and a material of the second resin layer (6) are different from each other.

With this aspect, for example, in a case where hardness of the first resin layer (5) is higher than hardness of the second resin layer (6), it is possible to improve coplanarity of the second connection terminals (72; 72A, 72B; 72G, H).

According to any one of the first to eighth aspects, in the radio frequency module (1; 1a to 1f) according to a tenth aspect, a material of the first resin layer (5) is the same as a material of the second resin layer (6).

With this aspect, since a coefficient of linear expansion of the first resin layer (5) and a coefficient of linear expansion of the second resin layer (6) are the same, separating is less likely to occur between the first resin layer (5) and the second resin layer (6).

According to any one of the first to tenth aspects, the radio frequency module (1a; 1b) according to an eleventh aspect further includes a bump (200). The bump (200) is disposed on a side of the second connection terminal (72) opposite to the first connection terminal (71) side. The bump (200) is located inside the first connection terminal (71) in the plan view in the thickness direction (D1) of the mounting substrate (2).

With this aspect, it is possible to reduce an increase in signal loss while achieving reduction in size of the radio frequency module (1a; 1b).

According to a twelfth aspect, there is provided a radio frequency module (1; 1a to 1g) includes a mounting substrate (2), a first electronic component (3A), a second electronic component (3B) and a first connection terminal (71; 71C to 71J), a second connection terminal (72; 72A, 72B; 72G, 72H; 721, 72J), a first resin layer (5), and a second resin layer (6). The mounting substrate (2) has a first main surface (21) and a second main surface (22) facing each other. The first electronic component (3A) is disposed on the first main surface (21) of the mounting substrate (2). The second electronic component (3B) and the first connection terminal (71; 71C to 71J) are disposed on a second main surface (22) of the mounting substrate (2). The second connection terminal (72; 72A, 72B; 72G, 72H; 721, 72J) is connected to the first connection terminal (71; 71C to 71J), and is disposed on a side of the first connection terminal (71; 71C to 71J) opposite to the mounting substrate (2) side. The first resin layer (5) covers at least a part of the second electronic component (3B), and covers at least a part of the first connection terminals (71; 71C to 71J). The second resin layer (6) is disposed on the first resin layer (5), and covers at least a part of the second connection terminals (72; 72A, 72B; 72G, 72H; 721, 72J). A shape of each of the first connection terminal (71; 71C to 71J) and the second connection terminal (72; 72A, 72B; 72G, 72H; 721, 72J) is a columnar shape. In a plan view in a thickness direction (D1) of the mounting substrate (2), an area (S11) of the first connection terminal (71; 71C to 71J) is larger than an area (S12) of the second connection terminal (72; 72A, 72B; 72G, 72H; 721, 72J).

With this aspect, it is possible to reduce an increase in signal loss while achieving reduction in size of the radio frequency module (1; 1a to 1g).

According to a thirteenth aspect, there is provided a communication device (100) including the radio frequency module (1; 1a to 1g) according to any one of the first to twelfth aspects, and a signal processing circuit (20). The signal processing circuit (20) is connected to the radio frequency module (1; 1a to 1g).

With this aspect, it is possible to reduce an increase in signal loss while achieving reduction in size of the radio frequency module (1; 1a to 1g).

According to a fourteenth aspect, there is provided a method of manufacturing a radio frequency module (1; 1a to 1f) includes a step of preparing a mounting substrate (2) having a first main surface (21) and a second main surface (22) facing each other. The method of manufacturing the radio frequency module (1; 1a to 1f) further includes a step of forming a metal member (700) on the second main surface (22) of the mounting substrate (2), and a step of disposing an electronic component (3B) on the second main surface (22) of the mounting substrate (2). The method of manufacturing the radio frequency module (1; 1a to 1f) further includes a step of forming a first resin member (500) on the second main surface (22) side of the mounting substrate (2) to cover at least a part of the electronic component (3B). The method of manufacturing the radio frequency module (1; 1a to 1f) further includes a step of forming a first resin layer (5) by polishing a main surface (501) of the first resin member (500) on an opposite side to the mounting substrate (2) side such that a main surface (711) of the first connection terminal (71; 71C to 71H) formed from the metal member (700), on an opposite side to the mounting substrate (2) side is exposed. The method of manufacturing the radio frequency module (1; 1a to 1f) further includes a step of forming a second resin member (600) on a side of the first resin layer (5) opposite to the mounting substrate (2) side, and a step of forming a second resin layer (6) by forming a through-hole (61) at a part of the second resin member (600) facing the first connection terminal (71; 71C to 71H) in a thickness direction (D1) of the mounting substrate (2). The method of manufacturing the radio frequency module (1; 1a to 1f) further includes a step of forming a second connection terminal (72; 72A, 72B; 72G, 72H) in the through-hole (61) of the second resin layer (6). The second connection terminal (72; 72A, 72B; 72G, 72H) is located inside the first connection terminal (71; 71C to 71H) in a plan view in the thickness direction (D1) of the mounting substrate (2).

With this aspect, it is possible to reduce an increase in signal loss while achieving reduction in size of the radio frequency module (1; 1a to 1f).

According to a fifteenth aspect, there is provided a method of manufacturing a radio frequency module (1; 1a to 1g) includes a step of preparing a mounting substrate (2) having a first main surface (21) and a second main surface (22) facing each other. The method of manufacturing the radio frequency module (1; 1a to 1g) further includes a step of forming a metal member (700) on the second main surface (22) of the mounting substrate (2), and a step of disposing an electronic component (3B) on the second main surface (22) of the mounting substrate (2). The method of manufacturing the radio frequency module (1; 1a to 1g) further includes a step of forming a first resin member (500) on the second main surface (22) side of the mounting substrate (2) to cover at least a part of the electronic component (3B). The method of manufacturing the radio frequency module (1; 1a to 1g) further includes a step of forming a first resin layer (5) by polishing a main surface (501) of the first resin member (500) on an opposite side to the mounting substrate (2) side such that a main surface (711) of the first connection terminal (71; 71C to 71H) formed from the metal member (700), on an opposite side to the mounting substrate (2) side is exposed. The method of manufacturing the radio frequency module (1; 1a to 1g) further includes a step of forming a second resin member (600) on a side of the first resin layer (5) opposite to the mounting substrate (2) side, and a step of forming a second resin layer (6) by forming a through-hole (61) at a part of the second resin member (600) facing the first connection terminal (71; 71C to 71J) in the thickness direction (D1) of the mounting substrate (2). The method of manufacturing the radio frequency module (1; 1a to 1g) further includes a step of forming a second connection terminal (72; 72A, 72B; 72G, 72H; 721, 72J) in the through- hole (61) of the second resin layer (6). A shape of each of the first connection terminal (71; 71C to 71J) and the second connection terminal (72; 72A, 72B; 72G, 72H; 721, 72J) is a columnar shape. In a plan view in the thickness direction (D1) of the mounting substrate (2), an area of the first connection terminal (71; 71C to 71J) is larger than an area of the second connection terminal (72; 72A, 72B; 72G, 72H; 721, 72J).

With this aspect, it is possible to reduce an increase in signal loss while achieving reduction in size of the radio frequency module (1; 1a to 1g).

### REFERENCE SIGNS LIST

1, 1a to 1g Radio frequency module
11 Transmission filter
12 Reception filter
13 Power amplifier
14 Low-noise amplifier
15 Output matching circuit
16 Input matching circuit
17, 18 Matching circuit
19 Switch
25 IC chip
2 Mounting substrate
21 First main surface
22 Second main surface
23 Conductive layer
24, 24A Via-conductor
3A First electronic component
3B Second electronic component (electronic component)
31 Main surface
4 Resin layer
5 Resin layer (first resin layer)
51 Main surface
500 Resin member (first resin member)
501 Main surface
6 Resin layer (second resin layer)
61 Through-hole
600 Resin member (second resin member)
7, 7A to 7J External connection terminal
71, 71C to 71J First connection terminal
700 Metal member
711 Main surface
72, 72A, 72B, 72G to 72J Second connection terminal
721 First layer
722 Second layer
723 Third layer
701 Antenna terminal
702 Signal input terminal
703 Signal output terminal
8 Metal electrode layer
20 Signal processing circuit
201 RF signal processing circuit
202 Baseband signal processing circuit
203 Antenna
100 Communication device
200 Bump
d1, d2, d21, d22 Diameter
D1 First direction (thickness direction)
D2 Second direction
D3 Third direction
G1, G2, G11, G22 Interval
L1 Length (distance)
L2 Length
L3, L4 Distance
S1, S2, S11, S22 Area

1. A radio frequency module comprising:
a mounting substrate that includes a first main surface and a second main surface facing each other;
a first electronic component disposed on the first main surface of the mounting substrate;
a second electronic component and a first connection terminal that are disposed on the second main surface of the mounting substrate;
a second connection terminal that is connected to the first connection terminal and is disposed on a side of the first connection terminal opposite to a mounting substrate side;
a first resin layer that covers at least a part of the second electronic component and covers at least a part of the first connection terminal; and
a second resin layer that is disposed on the first resin layer and covers at least a part of the second connection terminal,
wherein the second connection terminal is located inside the first connection terminal in a plan view in a thickness direction of the mounting substrate.

2. The radio frequency module according to claim 1,
wherein the first connection terminal is one of a plurality of first connection terminals,
the second connection terminal is one of a plurality of second connection terminals, and
an interval between two second connection terminals adjacent to each other in a second direction that intersects with a first direction, which is the thickness direction of the mounting substrate, among the plurality of second connection terminals is larger than an interval between two first connection terminals adjacent to each other in the second direction among the plurality of first connection terminals.

3. The radio frequency module according to claim 2,
wherein a length of the second connection terminal is smaller than a length of the first connection terminal in the thickness direction of the mounting substrate.

4. The radio frequency module according to claim 3,
wherein a material of the first connection terminal includes copper, and
a material of the second connection terminal includes gold.

5. The radio frequency module according to claim 3,
wherein a material of the first connection terminal and a material of the second connection terminal are the same.

6. The radio frequency module according to claim 5,
wherein a shape of each of the first connection terminal and the second connection terminal is a columnar shape, and
an area of the first connection terminal is larger than an area of the second connection terminal in the plan view in the thickness direction of the mounting substrate.

7. The radio frequency module according to claim 6,
wherein a shape of each of the first connection terminal and the second connection terminal is a cylindrical shape, and
a diameter of the first connection terminal is larger than a diameter of the second connection terminal in the plan view in the thickness direction of the mounting substrate.

8. The radio frequency module according to claim 7,
wherein a main surface of the second electronic component on an opposite side to the mounting substrate side, a main surface of the first connection terminal on an opposite side to the mounting substrate side, and a main surface of the first resin layer on an opposite side to the mounting substrate side have the same distance from the second main surface of the mounting substrate in the thickness direction of the mounting substrate.

9. The radio frequency module according to claim 8,
wherein a material of the first resin layer and a material of the second resin layer are different from each other.

10. The radio frequency module according to claim 8,
wherein a material of the first resin layer and a material of the second resin layer are the same.

11. The radio frequency module according to claim 10, further comprising:
a bump disposed on a side of the second connection terminal opposite to the first connection terminal side,
wherein the bump is located inside the first connection terminal in the plan view in the thickness direction of the mounting substrate.

12. A radio frequency module comprising:
a mounting substrate that includes a first main surface and a second main surface facing each other;
a first electronic component disposed on the first main surface of the mounting substrate;
a second electronic component and a first connection terminal that are disposed on the second main surface of the mounting substrate;
a second connection terminal that is connected to the first connection terminal and is disposed on a side of the first connection terminal opposite to a mounting substrate side;
a first resin layer that covers at least a part of the second electronic component and covers at least a part of the first connection terminal; and
a second resin layer that is disposed on the first resin layer and covers at least a part of the second connection terminal,
wherein a shape of each of the first connection terminal and the second connection terminal is a columnar shape, and
an area of the first connection terminal is larger than an area of the second connection terminal in a plan view in a thickness direction of the mounting substrate.

13. A communication device comprising:
the radio frequency module according to claim 1; and
a signal processing circuit connected to the radio frequency module.

14. The radio frequency module according to claim 1,
wherein a length of the second connection terminal is smaller than a length of the first connection terminal in the thickness direction of the mounting substrate.

15. The radio frequency module according to claim 1,
wherein a material of the first connection terminal includes copper, and a material of the second connection terminal includes gold.

16. The radio frequency module according to claim 1,
wherein a material of the first connection terminal and a material of the second connection terminal are the same.

17. The radio frequency module according to claim 1,
wherein a shape of each of the first connection terminal and the second connection terminal is a columnar shape, and
an area of the first connection terminal is larger than an area of the second connection terminal in the plan view in the thickness direction of the mounting substrate.

18. The radio frequency module according to claim 1,
wherein a shape of each of the first connection terminal and the second connection terminal is a cylindrical shape, and
a diameter of the first connection terminal is larger than a diameter of the second connection terminal in the plan view in the thickness direction of the mounting substrate.

19. The radio frequency module according to claim 1,
wherein a main surface of the second electronic component on an opposite side to the mounting substrate side, a main surface of the first connection terminal on an opposite side to the mounting substrate side, and a main surface of the first resin layer on an opposite side to the mounting substrate side have the same distance from the second main surface of the mounting substrate in the thickness direction of the mounting substrate.

20. The radio frequency module according to claim 1,
wherein a material of the first resin layer and a material of the second resin layer are different from each other.
